(19) United States
(12) Patent Application Publication
(10) Pub. No.: US 2004/0136427 A1
(43) Pub. Date: Jul. 15, 2004

(54) Semiconductor optical device

(76) Inventors: Jun-Ichi Hashimoto, Yokohama-shi (JP); Tsukuru Katsuyama, Yokohama-shi (JP)

Correspondence Address: SMITH, GAMBRELL & RUSSELL, LLP, 1850 M STREET, N.W., SUITE 800, WASHINGTON, DC, 20036, US

(21) Appl. No.: 10/667,142

(22) Filed: Sep. 22, 2003

Related U.S. Application Data
(60) Provisional application No. 60/470,849, filed on May 16, 2003.

(30) Foreign Application Priority Data
Sep. 19, 2002 (JP) P2002-273783

(51) Int. Cl. H01S 5/00

(52) U.S. Cl. 372/46

(57) ABSTRACT

This semiconductor light-emitting device 1 comprises a first conductivity type semiconductor region, an active layer, a second conductivity type semiconductor layer and current block semiconductor region. The first conductivity type semiconductor region is provided on a surface made of GaAs semiconductor. The active layer is provided on the first conductivity type semiconductor region. The active layer has a pair of side surfaces. The second conductivity type semiconductor layer is provided on the active layer. The second conductivity type semiconductor layer has a pair of side surfaces. The current block semiconductor region is provided on the side surfaces of the active layer and on the side surfaces of the second conductivity type semiconductor layer. The active layer is made of III-V compound semiconductor including at least nitrogen element as a V group member.

### RELATED APPLICATION DATA

The present application claims priority from U.S. Provisional Application No. 60/470,849 filed on May 16, 2003, the entirety of which is incorporated by reference herein for all purposes.

### BACKGROUND OF THE INVENTION

1. Field of the Invention

The present invention relates to a semiconductor optical device.

2. Related Background of the Invention

InGaAsP/InP semiconductor lasers are used as light sources for generating light having a wavelength of 1 micrometer or longer. The structures of the InGaAsP/InP semiconductor lasers can be a ridge type or buried heterostructure type.

Publication (Appl. Phys. Lett. 35(3), 1 Aug. 1979, pp. 232-235) discloses a semiconductor laser having a ridge structure. The semiconductor having a ridge structure comprises an active layer made of an InGaAsP semiconductor. The active layer is provided on the whole surface of a substrate, and is provided between a p-type InP semiconductor layer and an n-type InP semiconductor layer. Carriers, i.e., electrons and holes, are injected into the active layer through the stripe region of the ridge structure. Part of the injected carriers interact with photons in the active layer to generate light, whereas the remaining carriers, i.e., ineffective carriers, fail to interact with photons because the injected carriers spread within the active layer.

Another publication (IEEE JOURNAL OF QUANTUM ELECTRONICS, VOL. QE-17, NO. 2, FEBRUARY 1981, pp. 202-207) shows a buried heterostructure semiconductor laser. The buried heterostructure semiconductor laser has an active layer made of an InGaAsP semiconductor. The active layer is provided between a p-type InP semiconductor layer and an n-type InP semiconductor layer, and is provided between a current block portion made of InP semiconductor. Carriers are injected into the active layer. Due to heterobarrier between the active layer and the current block portion, the injected carriers are confined within the active layer.

### SUMMARY OF THE INVENTION

In order to confine carriers into the active layer, semiconductor lasers of such types are made of semiconductor materials that create a barrier height between the active layer and the semiconductor portion surrounding the active layer. If the active layer is made of an InGaAsP semiconductor, InP semiconductor can be combined with InGaAsP semiconductor to provide a heterobarrier therebetween. In this combination of the materials, InP semiconductor attains a barrier height of 2.16×10⁻¹⁹ joules (1.35 eV). What is demanded is, however, semiconductor optical devices having temperature characteristics superior to those of semiconductor optical devices made of InGaAsP and InP semiconductors.

Therefore, it is an object of the present invention to provide a semiconductor optical device having a temperature characteristic superior to those of InGaAsP/InP semiconductor optical devices.

According to one aspect of the present invention, a semiconductor optical device comprises: a first conductivity type semiconductor region; a semiconductor ridge; and a current block semiconductor region. The first conductivity type semiconductor region is provided on a surface of GaAs semiconductor and includes a primary surface having a first area and a second area. The semiconductor ridge includes an active layer and a second conductivity type semiconductor layer. The active layer is provided on the first area of the first conductivity type semiconductor region, and the second conductivity type semiconductor layer is provided on the active layer. The semiconductor ridge has a pair of side surfaces. The current block semiconductor region is provided on the following: the second area of the first conductivity type semiconductor region; and the side surfaces of the semiconductor ridge. The current block semiconductor region is provided for confining carriers in the semiconductor ridge. The active layer is made of III-V compound semiconductor including at least nitrogen (N) as a V group member. The active layer is provided to generate light having a wavelength of 0.9 micrometers or longer.

In the semiconductor optical device, the first conductivity type semiconductor region is made of semiconductor material enabling the first conductivity type semiconductor region to work as a etch stopper resistant to etchant for etching the active layer and the second conductivity type semiconductor layer.

Another aspect of the present invention, a semiconductor optical device comprises: a first conductivity type semiconductor region; an active layer; a second conductivity type semiconductor layer; and a current block semiconductor region. The first conductivity type semiconductor region is provided on a surface of GaAs semiconductor and has first and second semiconductor portions. The first semiconductor portion has a primary surface having a first area and a second area. The second semiconductor portion has a pair of side surfaces. The second semiconductor portion is provided on the first area of the first semiconductor portion. The active layer has a pair of side surfaces, and is provided on the second semiconductor portion of the first conductivity type semiconductor region. The second conductivity type semiconductor layer has a pair of side surfaces and is provided on the active layer. The current block semiconductor region is provided for confining carriers in the second semiconductor portion, the active layer and the second conductivity type semiconductor layer. The current block semiconductor region is provided on the following: the second area of the first semiconductor portion of the first conductivity type semiconductor region; the side surfaces of the second semiconductor portion; the side surfaces of the active layer; and the side surfaces of the second conductivity type semiconductor layer. The active layer is made of III-V compound semiconductor including at least nitrogen (N) as a V group member. The active layer is provided so as to generate light having a wavelength of 0.9 micrometers or longer.

In the semiconductor optical device, the active layer is made of III-V compound semiconductor including at least gallium (Ga) as a III group member. The III-V compound semiconductor of the active layer includes at least arsenic (As) as a V group member.

In the semiconductor optical device, the active layer is made of at least one of the following: GaInNAs semiconductor; GaNAs semiconductor; GaNAsSb semiconductor; GaNAsP semiconductor; GaNAsSbP semiconductor; GaInNAsSb semiconductor; GaInNAsP semiconductor; and GaInNAsSbP semiconductor.

In the semiconductor optical device, a refractive index of the active layer is higher than those of the current block semiconductor region, the first conductivity type semiconductor region, and the second conductivity type semiconductor layer.

The semiconductor optical device may further comprise an additional semiconductor layer containing III-V compound semiconductor. The additional semiconductor layer is provided between the first conductivity type semiconductor region and the active layer. A photoluminescence wavelength of the III-V compound semiconductor is between that of the active layer and that of the first conductivity type semiconductor region.

The semiconductor optical device may further comprise an additional semiconductor layer containing III-V compound semiconductor. The additional semiconductor layer is provided between the second conductivity type semiconductor layer and the active layer. A photoluminescence wavelength of the III-V compound semiconductor is between that of the active layer and that of the second conductivity type semiconductor layer.

The semiconductor optical device may further comprise a first SCH layer and a second SCH layer. The first SCH layer is provided between the first conductivity type semiconductor region and the active layer. The second SCH layer is provided between the second active layer and the second conductivity type semiconductor layer.

The semiconductor optical device may further comprise an additional semiconductor layer containing III-V compound semiconductor. The additional semiconductor layer is provided between the first conductivity type semiconductor region and the first SCH layer. A photoluminescence wavelength of the III-V compound semiconductor is between that of the first SCH layer and that of the first conductivity type semiconductor layer.

The semiconductor optical device may further comprise an additional semiconductor layer containing III-V compound semiconductor. The additional semiconductor layer is provided between the second conductivity type semiconductor layer and the second SCH layer. A photoluminescence wavelength of the III-V compound semiconductor is between that of the second SCH layer and that of the second conductivity type semiconductor layer.

In the semiconductor optical device, the current block semiconductor region comprises first and second current block layers. The conductivity type of the first current block layer is different from that of the second current block layer. The first conductivity type semiconductor region is made of (Al_{X1}Ga_{1-X1})_{Y1}In_{1-Y1}P semiconductor, where a composition X1 has a value within the range of zero or greater but not greater than 1. The second conductivity type semiconductor layer is made of (Al_{X2}Ga_{1-X2})_{Y2}In_{1-Y2}P semiconductor, where a composition X2 has a value within the range of zero or greater but not greater than 1. The first and second current block layers are made of (Al_{X3}Ga_{1-X3})_{Y3}In_{1-Y3}P semiconductor, where a composition X3 has a value within the range of zero or greater but not greater than 1.

In the semiconductor optical device, the current block semiconductor region comprises first and second current block layers. The conductivity type of the first current block layer is different from that of the second current block layer. The first conductivity type semiconductor region is made of an Al_{X1}Ga_{1-X1}As semiconductor, where a composition X1 has a value within the range of zero or greater but not greater than 1. The second conductivity type semiconductor layer is made of an Al_{X2}Ga_{1-X2}As semiconductor, where a composition X2 has a value within the range of zero or greater but not greater than 1. The first and second current block layers are made of Al_{X3}Ga_{1-X3}As semiconductor, where a composition X3 has a value within the range of zero or greater but not greater than 1.

In the semiconductor optical device, the first and second SCH layers are made of one of Al_{X}Ga_{1-X}As semiconductor (0≦X≦1) and Ga_{X}In_{1-X}As_{Y}P_{1-Y} semiconductor (about 0.5≦X≦1, 0≦Y≦1) that lattice-matches to GaAs semiconductor.

In the semiconductor optical device, the current block semiconductor region comprises first and second current block layers. The first and second current block semiconductor layers are made of material not containing aluminum as a III group element.

In the semiconductor optical device, the current block semiconductor region comprises first and second current block layers. The first and second current block semiconductor layers are made of material not containing aluminum as a III group element. The first conductivity type semiconductor region is made of material not containing aluminum as a III group element. The second conductivity type semiconductor layer is made of material not containing aluminum as a III group element.

In the semiconductor optical device, the surface of GaAs semiconductor is provided by one of a GaAs semiconductor layer and a gallium arsenide substrate.

In the semiconductor optical device, the semiconductor optical device is constituted to provide at least one of a semiconductor laser diode, a semiconductor optical amplifier, and an electro-absorption modulator.

### BRIEF DESCRIPTION OF THE DRAWINGS

The above-described object and other objects, features, and advantages of the present invention will become apparent more easily in the detailed description of the preferred embodiments of the present invention which will be described below with reference to the accompanying drawings.

FIG. 1 is a perspective view showing the semiconductor light-emitting device in accordance with the first embodiment;

FIG. 2A is a cross sectional view taken along the line I-I shown in FIG. 1;

FIG. 2B is a diagram showing the band gap taken along the line II-II of FIG. 2A;

FIG. 2C is a diagram showing the refractive index taken along the line II-II of FIG. 2A;

FIG. 2D is a diagram showing the band gap taken along the line III-III of FIG. 2A;

FIG. 2E is a diagram showing the refractive index taken along the line III-III of FIG. 2A;

FIG. 3A is a cross sectional view showing a modified example of the semiconductor optical device in accordance with the present embodiment;

FIG. 3B is a diagram showing the band gap taken along the line IV-IV of FIG. 3A;

FIG. 3C is a diagram showing the refractive index taken along the line IV-IV of FIG. 3A;

FIG. 4A is a cross sectional view showing a modified example of the semiconductor optical device in accordance with the present embodiment;

FIG. 4B is a diagram showing the band gap taken along the line V-V of FIG. 4A;

FIG. 4C is a diagram, showing the band gap of another semiconductor optical device taken along the line V-V of FIG. 4A.

FIG. 5 is a cross sectional view showing a modified example of the semiconductor optical device in accordance with the present invention.

FIG. 6 is a perspective view showing the semiconductor light-emitting device in accordance with the second embodiment.

FIG. 7A is a cross sectional view taken along the line VI-VI shown in FIG. 6;

FIG. 7B is a diagram showing the band gap taken along the line VII-VII of FIG. 7A;

FIG. 7C is a diagram showing the refractive index taken along the line VII-VII of FIG. 7A;

FIG. 7D is a diagram showing the band gap taken along the line VIII-VIII of FIG. 7A;

FIG. 7E is a diagram showing the refractive index taken along the line VIII-VIII of FIG. 7A;

FIG. 8A is a cross sectional view showing a modified example of the semiconductor optical device in accordance with the present embodiment;

FIG. 8B is a diagram showing the band gap taken along the line IX-IX of FIG. 8A;

FIG. 8C is a diagram, showing the refractive index of the semiconductor optical device taken along the line IX-IX of FIG. 8A.

FIG. 9A is a cross sectional view showing a modified example of the semiconductor optical device in accordance with the present embodiment;

FIG. 9B is a diagram showing the band gap taken along the line X-X of FIG. 9A;

FIG. 9C is a diagram, showing the band gap of another semiconductor optical device, taken along the line X-X of FIG. 9A;

FIG. 10 is a cross sectional view showing a modified example of the semiconductor optical device in accordance with the present embodiment;

FIG. 11 is a graph showing the current versus optical output characteristics of a GaInNAs laser diode at several operation temperatures; and

FIG. 12 is a graph showing the current versus optical output characteristics of the GaInNAs laser diode at a room temperature.

### DESCRIPTION OF THE PREFERRED EMBODIMENTS

The teachings of the present invention will readily be understood in view of the following detailed descriptions with reference to the accompanying drawings illustrated by way of example. Referring to the accompanying drawings, embodiments of the semiconductor optical device according to the present invention will now be explained. When possible, parts identical to each other will be referred to with numerals identical to each other.

### First Embodiment

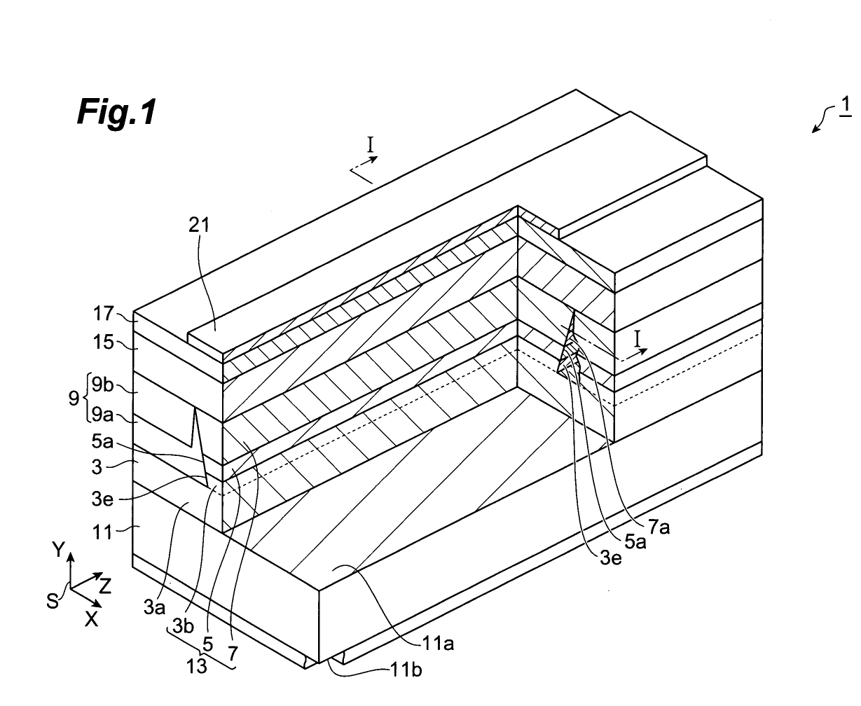

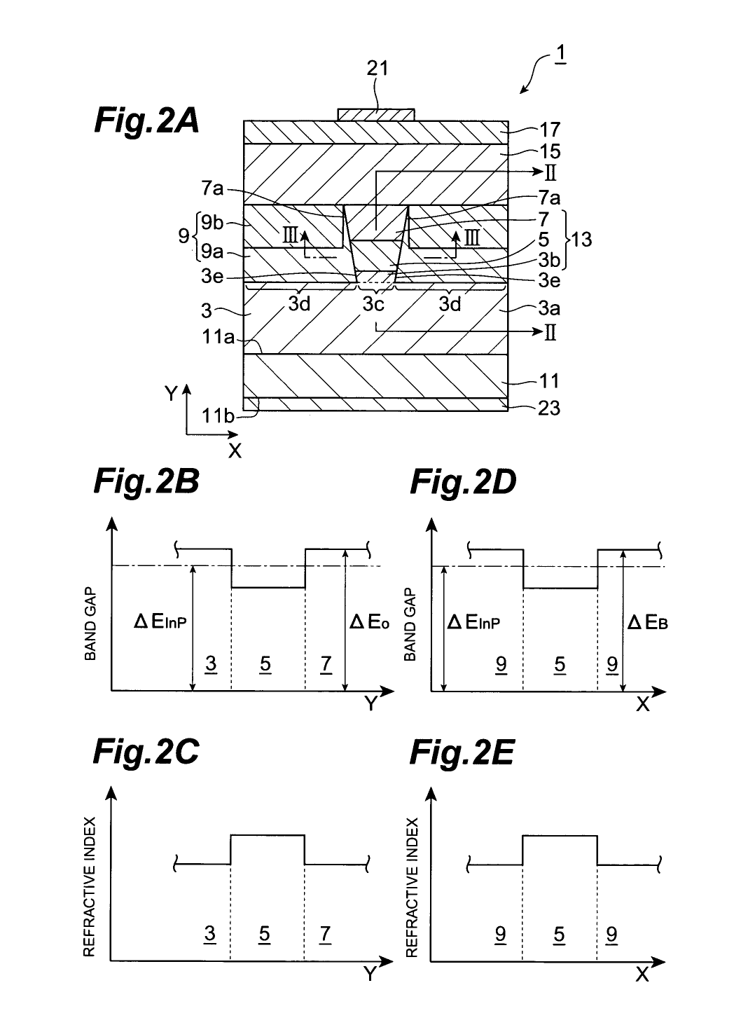

FIG. 1 is a perspective view showing the semiconductor light-emitting device in accordance with a first embodiment. XYZ coordinate system S is shown in FIG. 1. FIG. 2A is a cross sectional view taken along the line I-I shown in FIG. 1. FIG. 2B is a diagram showing the band gap taken along the line II-II of FIG. 2A. FIG. 2C is a diagram showing the refractive index taken along the line II-II of FIG. 2A. FIG. 2D is a diagram showing the band gap taken along the line III-III of FIG. 2A. FIG. 2E is a diagram showing the refractive index taken along the line III-III of FIG. 2A.

Referring to FIGS. 1 and 2A, a semiconductor light-emitting device 1, such as a buried heterostructure semiconductor laser device, is illustrated. This semiconductor optical device 1 comprises a first conductivity type semiconductor region 3, an active layer 5, a second conductivity type semiconductor layer 7, and a current block semiconductor region 9. The first conductivity type semiconductor region 3 is provided on a surface made of GaAs semiconductor, and has first and second semiconductor portions 3a and 3b. The first semiconductor portion 3a has a primary surface having a first region 3c and a second region 3d. The first region 3c is provided between the second regions 3d. The first region 3c extends along a predetermined axis. The second semiconductor portion 3b is provided on the first region 3c of the first semiconductor portion 3a. The second semiconductor portion 3b has a pair of side surfaces 3e. The active layer 5 is provided on the second semiconductor portion 3b of the first conductivity type semiconductor region 3. The active layer 5 has a pair of side faces 5a. The second conductivity type semiconductor layer 7 is provided on the active layer 5. The second conductivity type semiconductor layer 7 has a pair of side surfaces 7a. The current block semiconductor region 9 is provided on the following: the second region 3d of the first semiconductor portion 3a of the first conductivity type semiconductor region 3; each side surface 3e of the second semiconductor portion 3b; each side surface 5a of the active layer 5; and each side surface 7a of the second conductivity type semiconductor layer 7. The active layer 5 is made of a III-V compound semiconductor including at least nitrogen element as a V group member.

The semiconductor optical device 1 can include the active layer 5 that is provided on a GaAs substrate and is made of a III-V compound semiconductor including at least nitrogen as a V group member. Accordingly, in the semiconductor optical device 1, semiconductor materials lattice-matched to GaAs semiconductor and having a band gap higher than that of InP semiconductor can be used for the first conductivity type semiconductor region 3, the second conductivity type semiconductor layer 7, and the current block semiconductor region 9. The heterobarrier associated with the active layer 5 in the semiconductor optical device 1 can be made higher than that in InGaAsP/InP semiconductor optical devices.

Since the semiconductor optical device 1 has a buried heterostructure, it is superior to semiconductor lasers of a ridge structure in the confinement of carriers. Consequently, the semiconductor laser with a buried heterostructure lowers the ineffective current and enhances the interaction between carriers and photons, thereby attaining improvement in differential efficiency and reduction in the threshold current.

The first conductivity type semiconductor region 3 is made of by a III-V compound semiconductor, whereas this III-V compound semiconductor has a photoluminescence wavelength lower than that of the active layer 5. The second conductivity type semiconductor layer 7 is made of a III-V compound semiconductor, whereas this III-V compound semiconductor has a photoluminescence wavelength lower than that of the active layer 5. Here, the value of the photoluminescence wavelength is equal to the wavelength value corresponding to the band gap energy of the material. As shown in the band gap diagram of FIG. 2B, the first conductivity type semiconductor region 3 and the second conductivity type semiconductor layer 7 work so as to confine carriers into the active layer 5. As a result, the first conductivity type semiconductor region 3 can work as a cladding layer of the first conductivity type, whereas the second conductivity type semiconductor layer 7 can work as a second conductivity type cladding layer. After carriers are injected into the active layer 5 from the first conductivity type semiconductor region 3 and from the second conductivity type semiconductor layer 7, the carriers are confined into the active layer 5 and generate light.

As shown in FIG. 2B, the cladding layers of the semiconductor light-emitting device 1 exhibit a band gap value ΔE₀ higher than the band gap value ΔE_{InP} of a cladding layer made of InP semiconductor, in the InP/InGaAsP semiconductor light emitting device, so that the semiconductor light-emitting device 1 is superior to the InP/InGaAsP semiconductor light-emitting device in terms of the carrier confinement in the y direction.

The current block semiconductor region 9 is made of a III-V compound semiconductor, whereas this III-V compound semiconductor exhibits a photoluminescence wavelength value lower than that of the active layer 5. Therefore, as shown in the band gap diagram of FIG. 2D, the current block semiconductor region 9 works as a current block semiconductor layer. As shown in FIG. 2D, the current block semiconductor layer in the semiconductor light-emitting device 1 exhibits a band gap value ΔE_{B} higher than the band gap value ΔE_{InP} of the cladding layer made of InP semiconductor in the InP/InGaAsP semiconductor light-emitting device, whereby the semiconductor light-emitting device 1 is superior to the InP/InGaAsP semiconductor light-emitting device in terms of the carrier confinement in the x direction.

As shown in the refractive index distribution of FIG. 2C, the first conductivity type semiconductor region 3 exhibits a refractive index lower than that of the active layer 5. The second conductivity type semiconductor layer 7 exhibits a refractive index lower than that of the active layer 5. Therefore, the first conductivity type semiconductor region 3 and the second conductivity type semiconductor layer 7 acts to confine the light generated in the active layer 5 into the active layer 5 in the Y direction. As a result, the semiconductor region 3 works as an optical cladding layer of the first conductivity type, and the semiconductor layer 7 works as an optical cladding layer of the second conductivity type.

The current block semiconductor region 9 is made of III-V compound semiconductor, which exhibits a refractive index lower than that of the active layer 5. As a result, the current block semiconductor region 9 serves to confine light generated in the active layer 5 into the active layer 5, and acts as an optical cladding layer.

The semiconductor optical device 1 further comprises a semiconductor substrate 11. For example, a GaAs semiconductor substrate can be used as the semiconductor substrate 11. The surface of GaAs semiconductor on which the first conductivity type semiconductor region 3 is formed is provided by a GaAs semiconductor substrate. The first conductivity type semiconductor region 3 is provided on a primary surface 11a of the semiconductor substrate 11. The first conductivity type semiconductor region 3 includes the first portion 3a provided on the primary surface 11a of the semiconductor substrate 11, and the second portion 3b provided on the first portion 3a. The second portion 3b of the first conductivity type semiconductor region 3 is formed into a ridge, and is provided between the current block semiconductor region 9 which is provided on the first portion 3a. The active layer 5 and the second conductivity type semiconductor layer 7 are formed into a ridge, and are provided between the current block semiconductor region 9. The active layer 5 is provided between the second portion 3b of the first conductivity type semiconductor region 3 and the second conductivity type semiconductor layer 7. The second portion 3b of the first conductivity type semiconductor region 3, the active layer 5, and the second conductivity type semiconductor layer 7 constitute a semiconductor ridge 13. The semiconductor ridge 13 extends along the predetermined axis. In the semiconductor ridge 13, carriers are injected into the active layer 5 from the second conductivity type semiconductor layer 7 and from the second portion 3b of the first conductivity type semiconductor region 3.

The semiconductor optical device 1 further comprises a second conductivity type semiconductor layer 15 provided on the current block semiconductor region 9 and the semiconductor ridge 13. The second conductivity type semiconductor layer 15 exhibits a photoluminescence wavelength value equal to or shorter than that of the second conductivity type semiconductor layer 7, and shorter than that of the active layer 5. The second conductivity type semiconductor layer 15 exhibits a refractive index equal to or lower than that of the second conductivity type semiconductor layer 7, and lower than that of the active layer 5. Therefore, the second conductivity type semiconductor layer 15 acts to confine the generated light and injected carriers into the active layer 5. As a result, the semiconductor layer 15 works as an optical cladding layer of the second conductive type.

The semiconductor optical device 1 having such a refractive index structure and a band gap structure can enhance the carrier confinement in lateral transverse and vertical transverse directions, thereby lowering the threshold current, increasing the slope efficiency, and improving the temperature characteristic.

The semiconductor device 1 further comprises a second conductivity type semiconductor layer 17, and electrodes 21 and 23. The second conductivity type semiconductor layer 17 is provided on the second conductivity type semiconductor layer 15. The electrode 21 is provided on the second conductivity type semiconductor layer 17. The electrode 21 extends in the same direction as with the semiconductor ridge 13. The electrode 23 is provided on the rear surface 11b of the substrate 11. The band gap of the second conductivity type semiconductor layer 17 is smaller than that of the second conductivity type semiconductor layer 15. This makes it easier to realize ohmic contact between the second electrode 21 and the second conductivity type semiconductor layer 17. The second conductivity type semiconductor layer 17 acts as a contact layer.

In the semiconductor optical device 1, the current block semiconductor region 9 may have a first current block layer 9a and a second current block layer 9b. The conductivity type of the first current block layer 9a is different from that of the second current block layer 9b. Since the current block semiconductor region 9 includes these semiconductor layers that form a p-n junction, the p-n junction between the first current block layer 9a and the second current block layer 9b serves to block currents. The first and second current block layers 9a and 9b may be made of semiconductor materials of the second and first conductivity type, respectively.

In the semiconductor optical device 1 shown in FIGS. 1 and 2A, the first current block layer 9a is provided between the second current block layer 9b of the first conductivity type semiconductor and the first conductivity type semiconductor region 3, whereas the second current block layer 9b is provided between the first current block layer 9a of the second conductivity type semiconductor and the second conductivity type semiconductor layer 15. Hence, the second conductivity type semiconductor layer 15, first conductivity type semiconductor region 3 and current block semiconductor region 9 construct a p-n-p-n or n-p-n-p structure.

In a first example of the semiconductor light-emitting device 1,

the first conductivity type semiconductor region 3: n-type AlGaInP or GaInP;

the active layer 5: undoped (hereinafter referred to as “un”) GaInNAs, un-GaNAs, un-GaNAsSb, un-GaNAsP, un-GaNAsSbP, un-GaInNAsSb, un-GaInNAsP, and/or un-GaInNAsSbP;

the second conductivity type semiconductor layer 7: p-type AlGaInP semiconductor and/or GaInP semiconductor;

the second conductivity type semiconductor layer 15: p-type AlGaInP or GaInP;

the first current block semiconductor layer 9a: p-type AlGaInP semiconductor, p-type AlGaAs semiconductor, p-type GaAs semiconductor, or p-type GaInP semiconductor;

the second current block semiconductor layer 9b: n-type AlGaInP semiconductor, n-type GaInP semiconductor, n-type AlGaAs semiconductor, and/or n-type GaAs semiconductor;

the substrate 11: n-type heavily doped GaAs substrate; and

the contact layer 17: p-type GaAs semiconductor.

In the semiconductor optical device 1, the first conductivity type semiconductor region 3 and the second conductivity type semiconductor layer 7 may be made by an (Al_{X}Ga_{1-X})_{Y}In_{1-Y}P semiconductor lattice-matched to GaAs semiconductor, whereas each of the first and second current block layers 9a and 9b may be made of an Al_{X}Ga_{1-X}P semiconductor or an (Al_{X}Ga_{1-X})_{Y}In_{1-Y}P semiconductor that lattice-matches to GaAs semiconductor. In these semiconductor crystals, a composition “X” has a value within the range of zero or greater but not greater than 1. Using these semiconductor materials can improve the carrier confinement at the following interfaces: the active layer 5 and the current block semiconductor regions 9; the active layer 5 and the first conductivity type semiconductor region 3; and the active layer 5 and the second conductivity type semiconductor layer 7.

In a second example of the semiconductor light-emitting device 1,

the first conductivity type semiconductor region 3: n-type AlGaAs semiconductor and/or n-type GaAs semiconductor;

the active layer 5: un-GaInNAs, un-GaNAs, un-GaNAsSb, un-GaNAsP, un-GaNAsSbP, un-GaInNAsSb, un-GaInNAsP and/or un-GaInNAsSbP;

the second conductivity type semiconductor layer 7: p-type AlGaAs semiconductor and/or p-type GaAs semiconductor;

the second conductivity type semiconductor layer 15: p-type AlGaAs semiconductor and/or p-type GaAs semiconductor;

the first current block semiconductor layer 9a: p-type AlGaInP semiconductor, p-type AlGaAs semiconductor, p-type GaAs semiconductor, and/or p-type GaInP semiconductor;

the second current block semiconductor layer 9b: n-type AlGaInP semiconductor, n-type GaInP semiconductor, n-type AlGaAs semiconductor, and/or n-type GaAs semiconductor;

the substrate 11: heavily-doped n-type GaAs substrate; and

the contact layer 17: p-type GaAs semiconductor.

In the semiconductor optical device 1 of this example, the first conductivity type semiconductor region 3 and the second conductivity type semiconductor layer 7 may be made of an Al_{X}Ga_{1-X}As semiconductor, whereas each of the first and second current block layers 9a and 9b may be made of an Al_{X}Ga_{1-X}As semiconductor or an (Al_{X}Ga_{1-X})_{Y}In_{1-Y}P semiconductor that lattice-matches to GaAs semiconductor. In these semiconductor crystals, parameter “X” has a value within the range of zero or greater zero but not greater than 1. Using this semiconductor material can improve the carrier confinement at the following interfaces: the active layer 5 and the current block semiconductor region 9; the active layer 5 and the first conductivity type semiconductor region 3; and the active layer 5 and the second conductivity type semiconductor layer 7.

In the semiconductor optical device 1 containing the above-mentioned semiconductor materials, the active layer 5 is provided so as to generate light having a wavelength of 0.9 micrometers or longer.

In FIG. 2B, InP semiconductor has band gap, ΔE_{InP}, and the semiconductor material of the cladding layers of the semiconductor optical device 1 has band gap ΔE₀. As can be seen from FIG. 2B, band gap ΔE₀ is greater than band gap ΔE_{InP}. That is, the band gap difference of the hetero-junction between the active layer 5 (which is made of one of GaInNAs, GaNAs, GaNAsSb, GaNAsP, GaNAsSbP, GaInNAsSb, GaInNAsP, and GaInNAsSbP semiconductors) and p- and n-type cladding layers (which are made of p-type AlGaInP, n-type AlGaInP, p-type AlGaAs, or n-type AlGaAs semiconductor) can be made greater than the band gap difference between InP semiconductor and GaInAsP semiconductor, where InP semiconductor has a band gap energy of 2.16×10⁻¹⁹ joules (1.35 eV). This explanation similarly applies to the active layer 5 and the current block semiconductor region 9 shown in FIG. 2D.

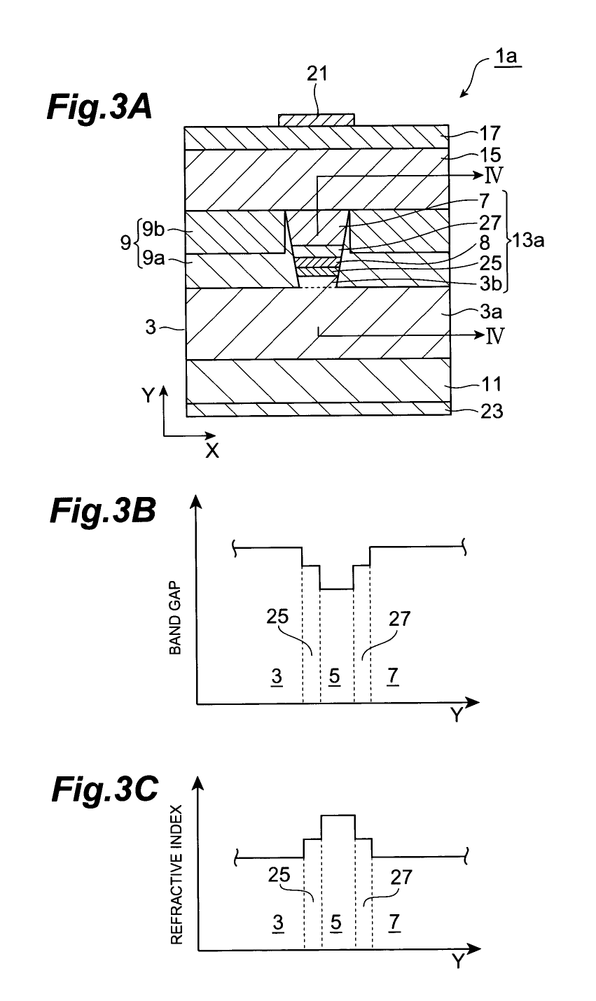

FIG. 3A is a cross sectional view showing a modified example of the semiconductor optical device in accordance with the first embodiment. FIG. 3B is a diagram showing the band gap taken along the line IV-IV of FIG. 3A. FIG. 3C is a diagram showing the refractive index taken along the line IV-IV of FIG. 3A. The semiconductor optical device la may further comprise a first SCH layer 25 and a second SCH layer 27. The first SCH layer 25 is provided between the first conductivity type semiconductor region 3 and the active layer 5. The second SCH layer 27 is provided between the active layer 5 and the second conductivity type semiconductor layer 7. The first and second SCH layers 25 and 27 are provided between the current block region 9. The second portion 3b of the first conductivity type semiconductor region 3, the active layer 5, the second conductivity type semiconductor layer 7, and the first and second SCH layers 25 and 27 constitute a semiconductor ridge 13a.

The photoluminescence wavelength of the first SCH layer 25 is between that of the active layer 5 and that of the first conductivity type semiconductor region 3. The second SCH layer 27 exhibits a photoluminescence wavelength having a value between that of the active layer 5 and that of the second conductivity type semiconductor layer 7. Carriers are injected into the active layer 5 by way of the first and second SCH layers 25 and 27 from the second conductivity type semiconductor layer 7 and the second portion 3b of the first conductivity type semiconductor region 3. In the semiconductor optical device 1a, as shown in FIG. 3B, the first and second SCH layers 25 and 27 act to confine the injected carriers into the active layer 5.

The refractive index of the first SCH layer 25 is between that of the active layer 5 and that of the first conductivity type semiconductor region 3. The refractive index of the second SCH layer 27 is between that of the active layer 5 and that of the second conductivity type semiconductor layer 7. As shown in FIG. 3C, the first semiconductor region 3 and the second conductivity type semiconductor layer 7 function to confine light generated in the active layer 5 into the active layer 5 and the first and second SCH layers 25 and 27.

The first and second SCH semiconductor layers 25 and 27 make it possible to confine carriers and light separately. These SCH layers function to enhance the confinement of light into the active layer 5, thereby providing the semiconductor light-emitting device 1a which improves the oscillation characteristics, such as a reduction in the threshold current, and the temperature characteristic.

Each of the first and second SCH layers may be made of an Al_{X}Ga_{1-X}As semiconductor (0≦X≦1) or a Ga_{X}In_{1-X}As_{Y}P_{1-Y} semiconductor (about 0.5≦X≦1, 0≦Y≦1) that lattice-matches to GaAs semiconductor. First and second examples of the semiconductor light-emitting device 1a are presented as follows:

the first and second SCH semiconductor layers 25, 27: un-Al_{X}Ga_{1-X}As (0≦X≦1), un-GaAs, and/or a Ga_{X}In_{1-X}As_{Y}P_{1-Y} semiconductor (about 0.5≦X≦1, 0≦Y≦1) lattice-matched to GaAs semiconductor.

In the above example, a GaInAsP semiconductor is provided so as to lattice-match to GaAs semiconductor. According to the above materials, the refractive indices of the first and second SCH semiconductor layers 25 and 27 fall within values between those of the first conductivity type semiconductor region 3 and second conductivity type semiconductor layer 7 and the refractive index of the active layer 5, and the photoluminescence wavelengths of the first and second SCH semiconductor layers 25 and 27 fall within values between those of the first conductivity type semiconductor region 3 and second conductivity type semiconductor layer 7 and the photoluminescence wavelength of the active layer 5. Accordingly, light and carriers can be confined into the active layer 5.

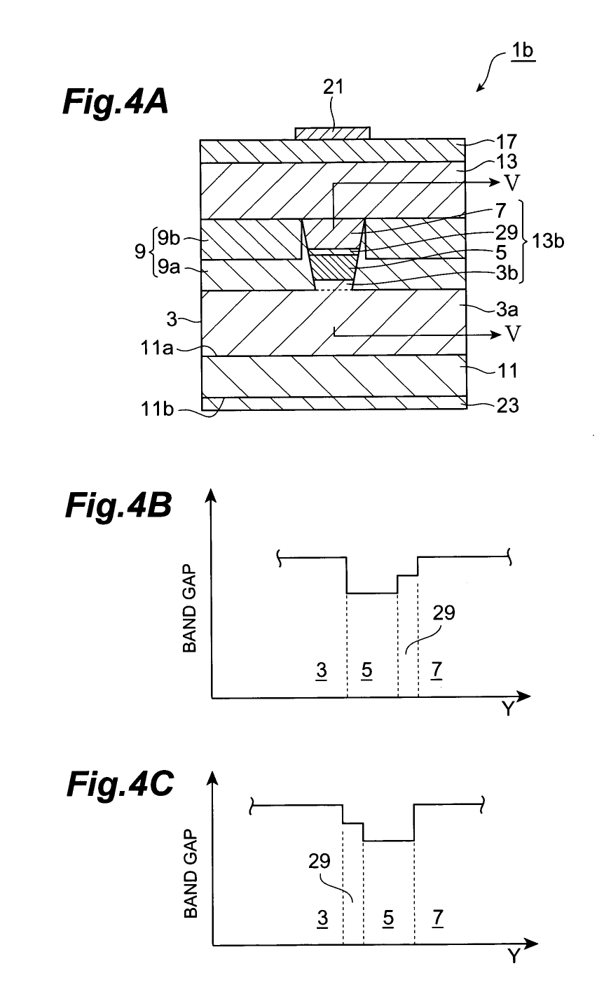

FIG. 4A is a cross sectional view showing a modified example of the semiconductor optical device in accordance with the first embodiment. FIG. 4B is a diagram showing the band gap taken along the line V-V of FIG. 4A. FIG. 4C is a diagram showing the band gap of another semiconductor optical device taken along the line V-V of FIG. 4A. The semiconductor optical device 1b may further comprise an additional semiconductor layer 29 made of a III-V compound semiconductor. The additional semiconductor layer 29 is provided in the following arrangements: between the first conductivity type semiconductor region 3 and the active layer 5; and between the second conductivity type semiconductor layer 7 and the active layer 5. If the additional semiconductor layer 29 is provided between the second conductivity type semiconductor layer 7 and the active layer 5 in the semiconductor optical device 1b, the III-V compound semiconductor of the additional semiconductor layer 29 exhibits a photoluminescence wavelength value between that of the active layer 5 and that of the second conductivity type semiconductor layer 7 as shown in FIG. 4B. If the additional semiconductor layer 29 is provided between the first conductivity type semiconductor region 3 and the active layer 5, the III-V compound semiconductor of the additional semiconductor layer 29 exhibits a photoluminescence wavelength value between that of the active layer 5 and that of the first conductivity type semiconductor region 3. The second portion 3b of the first conductivity type semiconductor region 3, the active layer 5, the second conductivity type semiconductor layer 7, and the additional semiconductor layer 29 constitute a semiconductor ridge 13b.

According to the relationship of photoluminescence wavelengths as above, the additional semiconductor layer 29 lower spikes and notches at the heterojunction interfaces, thereby alleviating the heterobarrier in the following arrangements: between the active layer 5 and the first conductivity type semiconductor region 3; between the active layer 5 and the second conductivity type semiconductor layer 7.

In FIG. 4A, the semiconductor light-emitting device 1b comprises the additional semiconductor layer 29 provided between the second conductivity type semiconductor layer 7 and the active layer 5, but it may be provided between the first conductivity type semiconductor region 3 and the active layer 5 as shown in FIG. 4C. Additional semiconductor layers may be provided on both sides of the active layer 5.

In the first and second examples in the semiconductor light-emitting device 1b, the semiconductor layer 29 is made of p-type AlGaAs, p-type AlGaInP, p-type GaInP, and/or p-type GaInAsP.

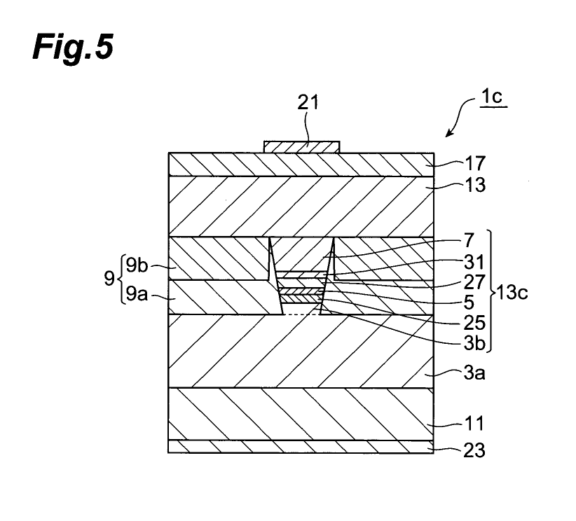

FIG. 5 is a cross sectional view showing a modified example of the semiconductor optical device in accordance with the first embodiment. The semiconductor optical device 1c shown in FIG. 5 may comprise SCH layers 25 and 27 and an additional semiconductor layer 31 made of a III-V compound semiconductor. The additional semiconductor layer 31 is provided between the second conductivity type semiconductor layer 7 and the second SCH layer 27. If the additional semiconductor layer 31 is provided between the second conductivity type semiconductor layer 7 and the second SCH layer 27 as in the semiconductor optical device 1c, the III-V compound semiconductor of the additional semiconductor layer 31 exhibits a photoluminescence wavelength value between that of the second SCH layer 27 and that of the second conductivity type semiconductor layer 7. If the additional semiconductor layer 31 is provided between the first conductivity type semiconductor region 3 and the first SCH layer 25, the III-V compound semiconductor of the additional semiconductor layer 31 has a photoluminescence wavelength value between that of the first SCH layer 25 and that of the first conductivity type semiconductor region 3. The second portion 3b of the first conductivity type semiconductor region 3, the active layer 5, the second conductivity type semiconductor layer 7, the first and second SCH layers 25 and 27, and the additional semiconductor layer 31 constitute a semiconductor ridge 13c.

The additional layer 31 may be provided in at least one of the interfaces in the following arrangements: between the first conductivity type semiconductor region 3 and the first SCH layer 25; and between the second conductivity type semiconductor layer 7 and the second SCH layer 27.

According to the relationship of photoluminescence wavelengths as above, the additional semiconductor layer 31 lowers spikes and notches at heterojunction interfaces, thereby alleviating the heterobarrier in the following arrangements: between the first SCH layer 25 and the first conductivity type semiconductor region 3; between the second SCH layer 27 and the second conductivity type semiconductor layer 7.

In the first and second examples of the semiconductor light-emitting device 1c, the semiconductor layer 31 is made of p-type AlGaAs, p-type AlGaInP, p-type GaInP, and/or p-type GaInAsP.

### Second Embodiment

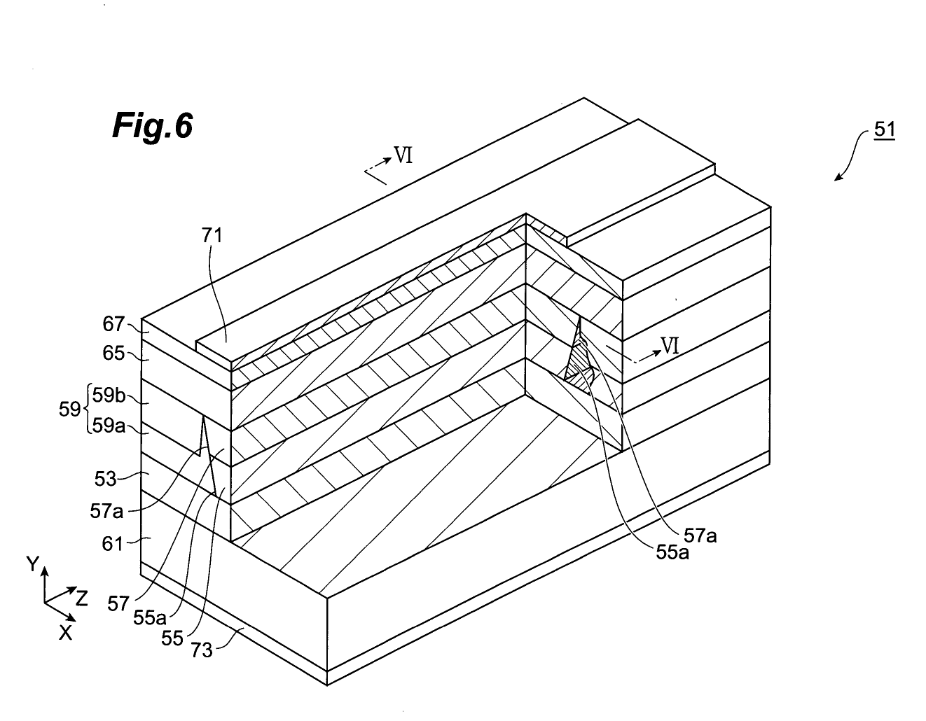

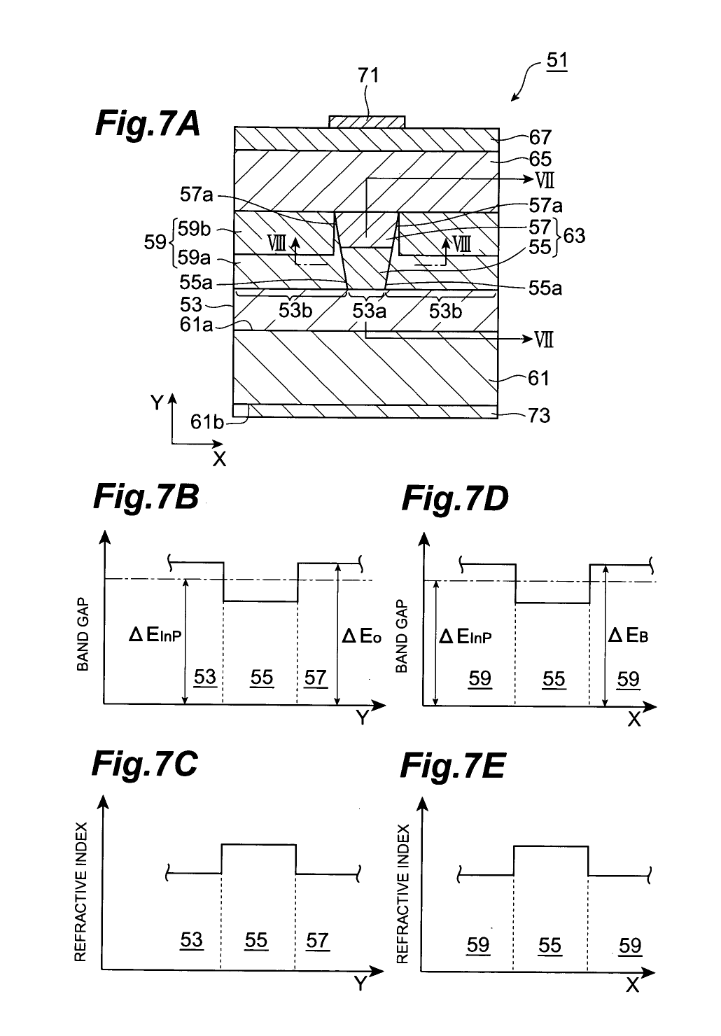

FIG. 6 is a perspective view showing the semiconductor light-emitting device of a second embodiment. XYZ coordinate system S is shown in FIG. 6. FIG. 7A is a cross sectional view showing the semiconductor light-emitting device taken along the line VI-VI shown in FIG. 6. FIG. 7B is a diagram showing the band gap taken along the line VII-VII of FIG. 7A. FIG. 7C is a diagram showing the refractive index taken along the line VII-VII of FIG. 7A. FIG. 7D is a diagram showing the band gap taken along the line VIII-VIII of FIG. 7A. FIG. 7E is a diagram showing the refractive index taken along the line VIII-VIII of FIG. 7A. Referring to FIGS. 6 and 7A, a semiconductor light-emitting device 51, such as a buried heterostructure semiconductor laser device, is shown.

This semiconductor optical device 51 comprises a first conductivity type semiconductor region 53, an active layer 55, a second conductivity type semiconductor layer 57, and a current block semiconductor region 59. The first conductivity type semiconductor region 53 is provided on a surface of GaAs semiconductor. The first conductivity type semiconductor region 53 comprises a primary surface having a first region 53a and a second region 53b. The first region 53a extends along a predetermined axis. The active layer 55 is provided on the first region 53a. The active layer 55 has a pair of side surfaces 55a. The second conductivity type semiconductor layer 57 is provided on the active layer 55. The second conductivity type semiconductor layer 57 has a pair of side surfaces 57a. The current block semiconductor region 59 is provided on the following regions: the second region 53b of the first conductivity type semiconductor region 53; each side surface 55a of the active layer 55; and each side surface 57a of the second conductivity type semiconductor layer 57. The active layer 55 is made of III-V compound semiconductor including at least nitrogen element as a V group member.

In the semiconductor optical device 51, the active layer 55 made of a III-V compound semiconductor containing at least nitrogen element as a V group member can be provided on a GaAs substrate, whereby the first conductivity type semiconductor region 53, the second conductivity type semiconductor layer 57, and the current block semiconductor region 59a can be made of semiconductor material lattice-matched to GaAs semiconductor and having a band gap higher than that of InP semiconductors. The heterobarriers around the active layer in such a semiconductor optical device can be made higher than that in InGaAsP/InP semiconductor optical devices.

The first conductivity type semiconductor region 53 is made of III-V compound semiconductor, and this III-V compound semiconductor exhibits a photoluminescence wavelength value shorter than that of the active layer 55. The second conductivity type semiconductor layer 57 is made of III-V compound semiconductor, and this III-V compound semiconductor exhibits a photoluminescence wavelength value shorter than that of the active layer 55. The photoluminescence wavelength value of the semiconductor material is equal to a wavelength value corresponding to its band gap energy. As shown in the band gap diagram of FIG. 7B, the first conductivity type semiconductor region 53 and the second conductivity type semiconductor layer 57 function to confine carriers into the active layer 55. Accordingly, the first conductivity type semiconductor region 53 functions as a first conductivity type cladding layer, whereas the second conductivity type semiconductor layer 57 functions as a second conductivity type cladding layer. The active layer 55 generates light in response to carriers confined therein and injected from the first conductivity type semiconductor region 53 and from the second conductivity type semiconductor layer 57. As shown in FIG. 7B, the semiconductor light-emitting device 51 has a cladding layer with a band gap value ΔE₀ higher than the band gap value ΔE_{InP} of a cladding layer made of InP semiconductor in an InP/InGaAsP semiconductor light-emitting device. Thus, the semiconductor light-emitting device 51 is superior to the InP/InGaAsP semiconductor light-emitting device in terms of the carrier confinement in the Y direction.

The current block semiconductor region 59 is made of a III-V compound semiconductor, whereas this III-V compound semiconductor exhibits a photoluminescence wavelength value shorter than that of the active layer 55. As a result, as shown in the band gap diagram of FIG. 7D, the current block semiconductor region 59 function as a semiconductor layer for blocking current. As shown in FIG. 7D, the semiconductor light-emitting device 51 has a current block semiconductor layer exhibiting a band gap value ΔE_{B} higher than the band gap value ΔE_{InP} of the InP current block semiconductor layer in the InP/InGaAsP semiconductor light-emitting device. Thus, the semiconductor light-emitting device 51 is superior to the InP/InGaAsP semiconductor light-emitting device in terms of the carrier confinement in the X direction.

As shown in the refractive index distribution of FIG. 7C, the first conductivity type semiconductor region 53 exhibits a refractive index lower than that of the active layer 55. The second conductivity type semiconductor layer 57 exhibits a refractive index lower than that of the active layer 55. Accordingly, the first conductivity type semiconductor region 53 and the second conductivity type semiconductor layer 57 function to confine light generated in the active layer 55 into the active layer 55. Consequently, the first conductivity type semiconductor region 53 works as an optical cladding layer, and the second conductivity type semiconductor layer 57 acts as an optical cladding layer.

The current block semiconductor region 59 is made of a III-V compound semiconductor, whereas this III-V compound semiconductor exhibits a refractive index lower than that of the active layer 55. Accordingly, the current block semiconductor region 59 functions to confine light generated in the active layer 55 into the active layer 55, and acts as an optical cladding layer.

The semiconductor optical device 51 further comprises a semiconductor substrate 61. A GaAs semiconductor substrate is shown as an example of the semiconductor substrate 61. A GaAs semiconductor substrate can realize the surface of GaAs semiconductor on which the first conductivity type semiconductor region 53 is formed. The first conductivity type semiconductor region 53 is provided on a primary surface 61a of the semiconductor substrate 61. The active layer 55 and the second conductivity type semiconductor layer 57 are provided between the current block semiconductor regions 59, and are formed into a ridge. The active layer 55 is provided between the second conductivity type semiconductor layer 57 and the first portion 53a of the first conductivity type semiconductor region 53. The active layer 55 and the second conductivity type semiconductor layer 57 constitute a semiconductor ridge 63. The semiconductor ridge 63 extends along a predetermined axis. In the semiconductor ridge 63, carriers are injected into the active layer 55 from the second conductivity type semiconductor layer 57 and from the first region 53a of the first conductivity type semiconductor region 53.

The semiconductor optical device 51 further comprises a second conductivity type semiconductor layer 65 provided on the current block semiconductor region 59 and the semiconductor ridge 63. The second conductivity type semiconductor layer 65 exhibits a photoluminescence wavelength value equal to or shorter than that of the second conductivity type semiconductor layer 57, and shorter than that of the active layer 55. The second conductivity type semiconductor layer 65 exhibits a refractive index equal to or lower than that of the second conductivity type semiconductor layer 57, and lower than that of the active layer 55. Accordingly, the second conductivity type semiconductor layer 65 confines the generated light and injected carriers into the active layer 55. The second conductivity type semiconductor layer 65 works as a cladding layer.

The semiconductor device 51 further comprises a second conductivity type semiconductor layer 67, and electrodes 71 and 73. The second conductivity type semiconductor layer 67 is provided on the second conductivity type semiconductor layer 65. The electrode 71 is provided on the second conductivity type semiconductor layer 67. The electrode 71 extends in the direction in which the semiconductor ridge 63 extends. The electrode 73 is provided on the rear side 61b of the substrate 61. The second conductivity type semiconductor layer 67 has a band gap smaller than that of the second conductivity type semiconductor layer 65. This makes it easier to form ohmic contact between the second electrode 71 and the second conductivity type semiconductor layer 67. Consequently, the second conductivity type semiconductor layer 67 works as a contact layer.

In the semiconductor optical device 51, the current block semiconductor region 59 may have a first current block layer 59a and a second current block layer 59b. The conductivity type of the first current block layer 59a is different from that of the second current block layer 59b. The current block semiconductor region 59 includes a p-n junction constituted by the first and second current block layers 59a and 59b. This p-n junction can block currents. The first and second current block layers 59a and 59b may be made of semiconductor materials of the second and first conductivity type, respectively.

In the semiconductor optical device 51, the first current block layer 59a is provided between the first conductivity type semiconductor region 53 and the second current block layer 59b of a first conductivity type semiconductor, whereas the second current block layer 59b is provided between the second conductivity type semiconductor layer 65 and the first current block layer 59a of a second conductivity type semiconductor. Hence, the second conductivity type semiconductor layer 65, the first conductivity type semiconductor region 53, and the current block semiconductor region 59 constructs a p-n-p-n or n-p-n-p structure.

In a first example of the semiconductor light-emitting device 51:

the first conductivity type semiconductor region 53: n-type AlGaInP semiconductor and/or n-type GaInP semiconductor;

the active layer 55: un-GaInNAs semiconductor, un-GaNAs semiconductor, un-GaNAsSb semiconductor, un-GaNAsP semiconductor, un-GaNAsSbP semiconductor, un-GaInNAsSb semiconductor, un-GaInNAsP semiconductor, and/or un-GaInNAsSbP semiconductor;

the second conductivity type semiconductor layer 57: p-type AlGaInP semiconductor and/or p-type GaInP semiconductor;

the second conductivity type semiconductor layer 65: p-type AlGaInP semiconductor and/or p-type GaInP semiconductor;

the first current block semiconductor layer 59a: p-type AlGaInP semiconductor, p-type AlGaAs semiconductor, p-type GaAs semiconductor, and/or p-type GaInP semiconductor;

the second current block semiconductor layer 59b: n-type AlGaInP semiconductor, n-type GaInP semiconductor, n-type AlGaAs semiconductor, and/or n-type GaAs semiconductor;

the substrate 61: heavily-doped n-type GaAs substrate; and

the contact layer 67: p-type GaAs semiconductor.

In the semiconductor optical device 51, the first conductivity type semiconductor region 53 and the second conductivity type semiconductor layer 57 may be made of an (Al_{X}Ga_{1-X})_{Y}In_{1-Y}P semiconductor that lattice-matches to GaAs semiconductor, whereas each of the first and second current block layers 59a and 59b may be made of an Al_{X}Ga_{1-X}As semiconductor and/or an (Al_{X}Ga_{1-X})_{Y}In_{1-Y}P semiconductor that lattice-matches to GaAs semiconductor. In these semiconductor crystals, composition “X” has a value within the range of zero or greater but not greater than 1. Using this semiconductor material can improve the carrier confinement in the following arrangements: between the active layer 55 and the current block semiconductor region 59; between the active layer 55 and the first conductivity type semiconductor region 53; and between the active layer 55 and the second conductivity type semiconductor layer 57.

In a second example of the semiconductor light-emitting device 51:

the first conductivity type semiconductor region 53: n-type AlGaAs semiconductor and/or n-type GaAs semiconductor;

the active layer 55: un-GaInNAs semiconductor, un-GaNAs semiconductor, un-GaNAsSb semiconductor, un-GaNAsP semiconductor, un-GaNAsSbP semiconductor, un-GaInNAsSb semiconductor, un-GaInNAsP semiconductor, and/or un-GaInNAsSbP semiconductor;

the second conductivity type semiconductor layer 57: p-type AlGaAs semiconductor and/or p-type GaAs semiconductor;

the second conductivity type semiconductor layer 65: p-type AlGaAs semiconductor and/or p-type GaAs semiconductor;

the first current block semiconductor layer 59a: p-type AlGaInP semiconductor, p-type AlGaAs semiconductor, p-type GaAs semiconductor, and/or p-type GaInP semiconductor;

the second current block semiconductor layer 59b: n-type AlGaInP semiconductor, n-type GaInP semiconductor, n-type AlGaAs semiconductor, and/or n-type GaAs semiconductor;

the substrate 61: heavily-doped n-type GaAs substrate; and

the contact layer 67: p-type GaAs semiconductor.

In the semiconductor optical device 51, the first conductivity type semiconductor region 53 and the second conductivity type semiconductor layer 57 may be made of an Al_{X}Ga_{1-X}As semiconductor, whereas each of the first and second current block layers 59a and 59b may be made of an Al_{X}Ga_{1-X}As semiconductor and/or an (Al_{X}Ga_{1-X})_{Y}In_{1-Y}P semiconductor that lattice-matches to GaAs semiconductor. In these semiconductor crystals, composition “X” has a value within the range of zero or greater but not greater than 1. Using these semiconductor materials can improve the carrier confinement at the following interfaces: between the active layer 55 and the current block semiconductor regions 59; and between the active layer 55 and the first conductivity type semiconductor region 53; and between the active layer 55 and the second conductivity type semiconductor layer 57.

Therefore, the carrier confinement in transverse lateral and transverse vertical directions is enhanced in the semiconductor light-emitting device 51, whereby the semiconductor light-emitting device 51 has a lower threshold current, a higher slope efficiency, and an improved temperature characteristic as compared with InP/GaInAsP semiconductors semiconductor laser devices.

In the semiconductor optical device 51 made of the above-mentioned semiconductor materials, the active layer 55 is provided so as to generate light having a wavelength of 0.9 micrometers or longer.

InP semiconductor has the band gap ΔE_{InP} and the cladding layers have band gap ΔE₀ shown in FIG. 7B. As can be seen from FIG. 7B, the band gap, ΔE₀, is greater than the band gap ΔE_{InP}. That is, the band gap difference between the active layer (made of one of GaInNAs, GaNAs, GaNAsSb, GaNAsP, GaNAsSbP, GaInNAsSb, GaInNAsP, and GaInNAsSbP semiconductors) and the cladding layer (p-type AlGaInP, n-type AlGaInP, p-type AlGaAs, or n-type AlGaAs semiconductor) can be made greater than the band gap difference between InP semiconductor (having a band gap energy of 2.16×10⁻¹⁹ joules (1.35 eV)) and GaInAsP semiconductor. This explanation similarly applies to the active layer 55 and the current block semiconductor region 59 shown in FIG. 7D.

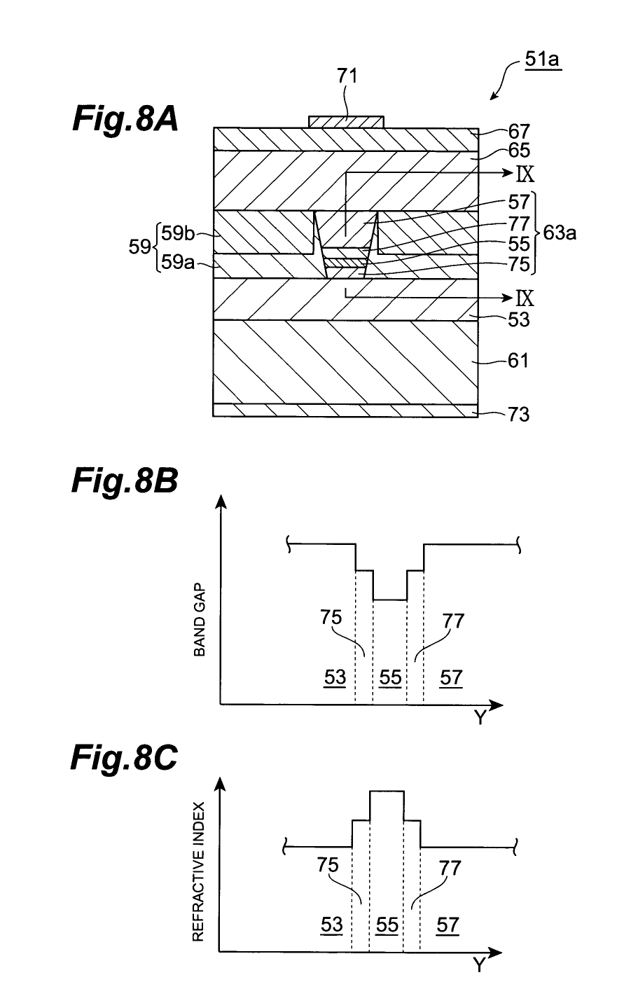

FIG. 8A is a cross sectional view showing a modified example of the semiconductor optical device in accordance with the present embodiment. FIG. 8B is a diagram showing the band gap taken along the line IX-IX of FIG. 8A. FIG. 8C is a diagram showing the refractive index taken along the line IX-IX of FIG. 8A. The semiconductor optical device 51a may further comprise a first SCH layer 75 and a second SCH layer 77. The first SCH layer 75 is provided between the first conductivity type semiconductor region 53 and the active layer 55. The second SCH layer 77 is provided between the active layer 55 and the second conductivity type semiconductor layer 57. The first and second SCH layers 75 and 77 are provided between the current block region 59. The first conductivity type semiconductor region 53, the active layer 55, the second conductivity type semiconductor layer 57, and the first and second SCH layers 75, 77 constitute a semiconductor ridge 63a.

The first SCH layer 75 exhibits a photoluminescence wavelength value between that of the active layer 55 and that of the first conductivity type semiconductor region 53. The second SCH layer 77 exhibits a photoluminescence wavelength value between that of the active layer 55 and that of the second conductivity type semiconductor layer 57. Carriers are injected into the active layer 55 from the first region 53a of the first conductivity type semiconductor region 53 and from the second conductivity type semiconductor layer 57 by way of the first and second SCH layers 75 and 77. In the semiconductor optical device 51a, as shown in FIG. 8B, the first and second SCH layers 75 and 77 functions to confine the injected carriers into the active layer 55.

The first SCH layer 75 exhibits a refractive index value between that of the active layer 55 and that of the first conductivity type semiconductor region 53. The second SCH layer 77 exhibits a refractive index value between that of the active layer 55 and that of the second conductivity type semiconductor layer 57. As shown in FIG. 8C, the first semiconductor region 53 and the second conductivity type semiconductor layer 57 function to confine light generated in the active layer 55 into the active layer 55 and the first and second SCH layers 75 and 77.

The first and second SCH semiconductor layers 75 and 77 make it possible to confine current and light separately. These SCH layers enhance the confinement of light into the active layer 55, thereby improving oscillation characteristics, such as a reduction in the threshold current, and temperature characteristic of the semiconductor optical device.

The first and second SCH layers 75 and 77 may be made of an Al_{X}Ga_{1-X}As semiconductor (0≦X≦1) or a Ga_{X}In_{1-X}As_{Y}P_{1-Y} semiconductor (about 0.5≦X≦1, 0≦Y≦1) that lattice-matches to GaAs semiconductor. In the first and second examples of the semiconductor light-emitting device 51a:

the SCH semiconductor layers 75 and 77: un-Al_{X}Ga_{1-X}As (0≦X≦1), un-GaAs, and/or a Ga_{X}In_{1-X}As_{Y}P_{1-Y} semiconductor (about 0.5≦X≦1, 0≦Y≦1) lattice-matched to GaAs semiconductor. In a preferred example, GaInAsP semiconductor is provided so as to lattice-match to GaAs. According to these materials, the refractive indices of the first and second SCH semiconductor layers 75 and 77 are between the refractive indices of the first conductivity type semiconductor region 53 and second conductivity type semiconductor layer 57 and the refractive index of the active layer 55, and the photoluminescence wavelengths of the first and second SCH semiconductor layers 75 and 77 are between photoluminescence wavelengths of the first conductivity type semiconductor region 53 and second conductivity type semiconductor layer 57 and the photoluminescence wavelength of the active layer 55. Accordingly, the light and carriers can be confined into the active layer 55.

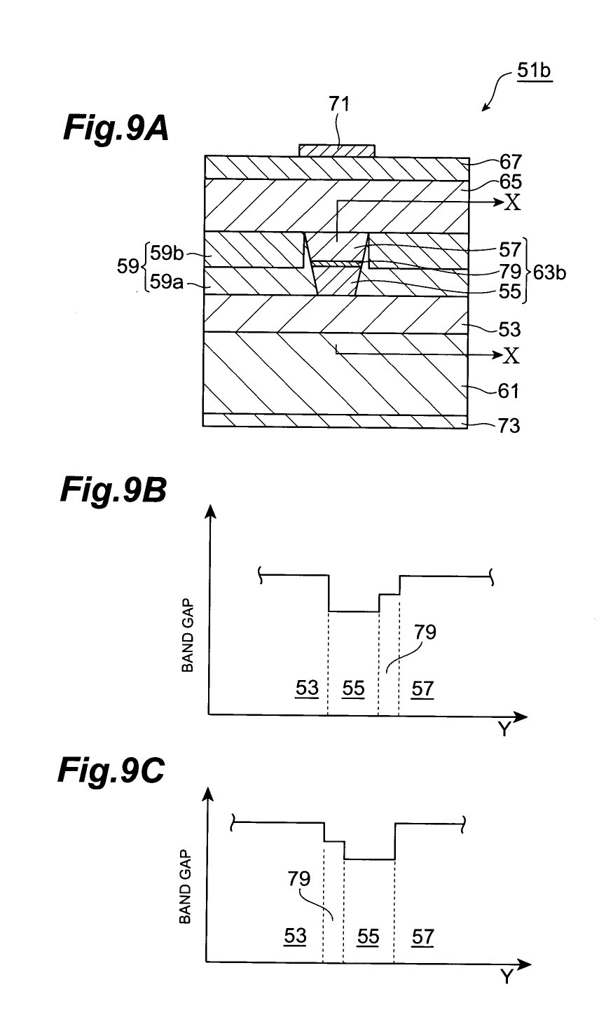

FIG. 9A is a cross sectional view showing a modified example of the semiconductor optical device in accordance with the present embodiment. FIG. 9B is a diagram showing the band gap taken along the line X-X of FIG. 9A. FIG. 9C is a diagram showing the band gap of another semiconductor optical device taken along the line X-X of FIG. 9A. The semiconductor optical device 51b may further comprise an additional semiconductor layer 79 made of a III-V compound semiconductor. In the semiconductor optical device 51b, the additional semiconductor layer 79 is provided between the second conductivity type semiconductor layer 57 and the active layer 55. The III-V compound semiconductor of the additional semiconductor layer 79 exhibits a photoluminescence wavelength value between that of the active layer 55 and that of the second conductivity type semiconductor layer 57. The active layer 55, the second conductivity type semiconductor layer 57, and the additional semiconductor layer 79 constitute a semiconductor ridge 63b.

In FIG. 9A, the semiconductor light-emitting device 51b has the additional semiconductor layer 79 provided between the second conductivity type semiconductor layer 57 and the active layer 55, but it may be provided between the first conductivity type semiconductor region 53 and the active layer 55 as shown in FIG. 9C. If the additional semiconductor layer 79 is provided between the first conductivity type semiconductor region 53 and the active layer 55, the III-V compound semiconductor of the additional semiconductor layer 79 exhibits a photoluminescence wavelength value between that of the first conductivity type semiconductor region 53 and that of the active layer 55. A pair of additional semiconductor layers may be provided on both sides of the active layer 55 as well. That is, the additional semiconductor layer 79 may be provided in at least one of following interfaces: between the first conductivity type semiconductor region 53 and the active layer 55; between the second conductivity type semiconductor layer 57 and the active layer 55.

According to this relationship of photoluminescence wavelengths, the additional semiconductor layer 79 lowers spikes and notches at the following interfaces: between the active layer 55 and the first conductivity type semiconductor region 53; between the active layer 55 and the second conductivity type semiconductor layer 57. Therefore, the heterobarriers at those interfaces are alleviated.

The first and second examples of the semiconductor light-emitting device 51b are shown below, the semiconductor layer 79: p-type AlGaAs, p-type AlGaInP, p-type GaInP, and/or p-type GaInAsP semiconductor.

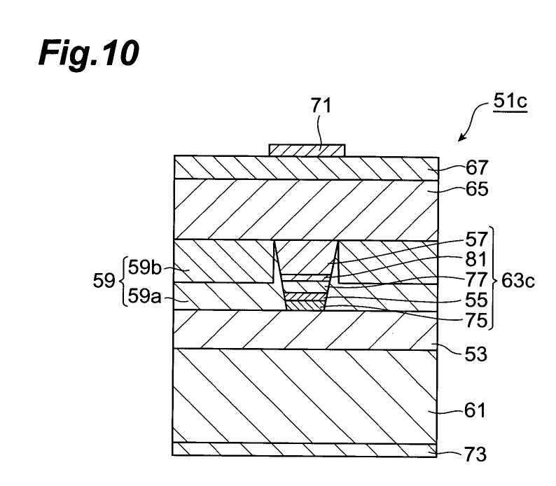

FIG. 10 is a cross sectional view showing a modified example of the semiconductor optical device in accordance with the present embodiment. The semiconductor optical device 51c including SCH layers 75 and 77 may further include an additional semiconductor layer 81 made of a III-V compound semiconductor. The additional semiconductor layer 81 is provided in at least one of following interfaces: between the first conductivity type semiconductor region 53 and the first SCH layer 75; between the second conductivity type semiconductor layer 57 and the second SCH layer 77. If the additional semiconductor layer 81 is provided between the second conductivity type semiconductor layer 57 and the second SCH layer 77 as in the semiconductor optical device 51c shown in FIG. 10A, the III-V compound semiconductor of the additional semiconductor layer 81 exhibits a photoluminescence wavelength value between that of the second SCH layer 77 and that of the second conductivity type semiconductor layer 57. If the additional semiconductor layer 81 is provided between the first conductivity type semiconductor region 53 and the first SCH layer 75, the III-V compound semiconductor of the additional semiconductor layer 81 has a photoluminescence wavelength value between that of the first SCH layer 75 and that of the first conductivity type semiconductor region 53. The active layer 55, the second conductivity type semiconductor layer 57, the first and second SCH layers 75 and 77, and the additional semiconductor layer 81 constitute a semiconductor ridge 63c. The semiconductor layer 81 of the semiconductor light-emitting device 51c can be made of the same material as the semiconductor layer 79.

According to this photoluminescence wavelength relationship, the additional semiconductor layer 81 lowers spikes and notches at the following heterojunction interfaces: between the SCH layer 75 and the first conductivity type semiconductor region 53; between the SCH layer 77 and the second conductivity type semiconductor layer 57. The heterobarriers at these interfaces are thereby alleviated.

Although the first and second embodiments of the present invention are described with reference to a number of modified examples in the foregoing, the embodiments are not limited thereto. In the semiconductor optical device in accordance with a further modified example, each of the first and second current block semiconductor layers are made of a III-V compound semiconductor including no aluminum (Al) as a III group element. If the first and second current block semiconductor layers are made of semiconductor materials including Al, the Al may be gradually oxidized with time around the interface between an active layer and a current block semiconductor region, thereby increasing the number of non-radiative recombination centers. If the first and second current block semiconductor layers do not contain Al as a III group member, there is no occurrence of Al oxidization that deteriorates the characteristics and reliability of the semiconductor light-emitting device. A GaInP semiconductor can be presented as an example of III-V compound semiconductor that includes no Al as a III group member. In a preferred example, the GaInP semiconductor lattice-matches to GaAs semiconductor.

If a III-V semiconductor material including Al is used as material for a current block semiconductor region, Al oxidization may occur in the step of burying the semiconductor ridge including an active layer at the following interfaces: between the current block semiconductor region and the semiconductor ridge; and/or between the current block semiconductor region and a first conductivity type semiconductor region. Thus, the current block semiconductor region with a favorable crystal quality cannot be provided due to the Al oxidization. For example, GaInP semiconductors do not include Al, and thus do not incur such a problem coming from the Al oxidization. The band gap of GaInP semiconductors is greater than that of III-V semiconductors including nitrogen (N). A current block semiconductor region made of a GaInP semiconductor favorably confines carriers into an active layer. Further, the refractive index of GaInP semiconductors is lower than that of III-V semiconductors including nitrogen (N). A current block semiconductor region made of a GaInP semiconductor favorably confines light in lateral transverse directions into an active layer.

While the current block semiconductor region is made of a GaInP semiconductor, the active layer may be made of a semiconductor including no Aluminum (Al) as a III group member and the first conductivity type semiconductor region and second conductivity type semiconductor layer may be made of a GaInP semiconductor. In this semiconductor light-generating device, the emission characteristic of the active layer is not deteriorated due to Al oxidization and the crystal quality of the current block semiconductor region is not degraded due to Al oxidization in a burying step. If the second conductivity type semiconductor layer and the current block semiconductor region are made of materials that does not contain Aluminum (Al) as a III group member, an additional second conductivity type semiconductor layer can be grown on the current block semiconductor region and second conductivity type semiconductor layer without the degradation of the crystal quality due to Al oxidization. Thus, the buried hetero-structure semiconductor light-emitting device has higher performances and higher reliability.

In the semiconductor light-emitting device having a light-generating region including the active layer made of III-V semiconductor including no aluminum as a III group member and a heterobarrier alleviating layer made of a GaInAsP semiconductor, the first conductivity type semiconductor region, the second conductivity type semiconductor layer, and the current block semiconductor region may be made of GaInP semiconductor. In a preferred example, the GaInP semiconductor lattice-matched to GaAs semiconductor is used. In this configuration, semiconductor layers constituting the semiconductor optical device are made of semiconductors without Al acting as a III group member, so that there is no occurrence of degradation of the reliability and emission characteristics of the semiconductor optical device due to the Al oxidization.

In the semiconductor optical device having a light-emitting region including an active layer made of III-V semiconductor including no Al as a III group member and an SCH layer, for example, the SCH layer may be made of at least one of GaAs and GaInAsP semiconductors, whereas the first conductivity type semiconductor region, second conductivity type semiconductor layer and the current block semiconductor region may be made of a GaInP semiconductor. In a preferred example, the GaInP and GaInAsP semiconductors lattice-matched to GaAs semiconductor can be used. Since the semiconductor layers constituting the semiconductor optical device do not include Al, the reliability and emission characteristics of the semiconductor optical device is not degraded due to the Al oxidization.

In the semiconductor optical device having a light-emitting region including SCH layers and an active layer that are made of III-V semiconductor without Al as a III group member, for example, the SCH layer may be made of at least one of GaAs and GaInAsP semiconductors. Further, the heterobarrier alleviating layer may be made of a GaInAsP semiconductor. Furthermore, the first conductivity type semiconductor region, second conductivity type semiconductor layer and the current block semiconductor region may be made of a GaInP semiconductor. In a preferred example, the GaInP and GaInAsP semiconductors lattice-matched to GaAs semiconductor can be used. Since the semiconductor layers constituting the semiconductor optical device are made of semiconductors without Al acting as a III group member, the reliability and emission characteristics of the semiconductor optical device is not degraded because of the Al oxidization.

In the foregoing, the semiconductor optical device including a semiconductor light-emitting element such as laser diode is described in the first and second embodiments, but the embodiments of the semiconductor optical device is not limited to the semiconductor light-emitting device. The semiconductor optical device may include any of a semiconductor laser diode, a semiconductor optical amplifier, and an electroabsorption modulator. Furthermore, the semiconductor optical device may be an optical integrated device composed of a plurality of components, such as a semiconductor laser diode, semiconductor optical amplifier, and electro-absorption modulator.

The structures disclosed in the embodiments make it possible to enhance the confinement of carriers in any of the semiconductor laser, semiconductor optical amplifier, electro-absorption modulator, and the optical integrated device by use of semiconductor material having a band gap higher than that of InP semiconductor, thereby improving their temperature characteristics as compared with InGaAsP/InP semiconductor optical devices.

Preferably, III-V compound semiconductor of the active layer in the first and second embodiments includes at least gallium element (Ga) as a III group member, and at least arsenic element (As) and nitrogen element (N) as V group members. The lattice constant of this material can be made identical or close to that of a GaAs semiconductor, so that the active layer can be grown on the GaAs semiconductor.

In the semiconductor optical devices 1 and 51, the band gap energy difference at hetero-junctions between the active layer and the second conductivity type semiconductor layer, between the active layer and the first conductivity type semiconductor region, between the active layer and the first current block layer, and between the active layer and the second current block layer are larger than those of the InP/InGaAsP semiconductors. Therefore, the structures of the semiconductor optical devices 1 and 51 can be improve the carrier confinement in the active layer.

In the semiconductor optical devices in accordance with the present embodiments, III-V compound semiconductor including nitrogen (N) can be used in the active layer. For example, one candidate of the III-V compound semiconductor including nitrogen (N) is a III-V compound semiconductor including at least nitrogen (N), gallium (Ga) and arsenic (As). This III-V semiconductor has a lattice constant identical or close to that of GaAs. Therefore, the III-V compound semiconductor crystal can favorably be grown on a GaAs semiconductor surface. The III-V compound semiconductor including at least nitrogen (N), gallium (Ga), and arsenic (As) has a band gap corresponding to a wavelength band of 0.9 micrometers or longer. Hence, using this III-V compound semiconductor in the active layer can realize semiconductor light-emitting devices that generate light having a wavelength of 0.9 micrometers or longer, e.g., light sources for 1.3-micrometer band optical communication or light sources for 1.55-micrometer band optical communication.

GaInAs and GaInAsP semiconductor crystals can be grown on a GaAs substrate to form an active layer of an optical device. But, the difference between the lattice constants of these crystals and the lattice constant of the GaAs substrate becomes too large in an oscillation wavelength of 1 micrometer or longer, resulting in excessive strains in the crystal of the active layer. Due to the excessive strains, the quality of the crystal is likely to deteriorate. Therefore, the optical semiconductor device cannot attain favorable oscillation characteristics and reliability. By contrast, a III-V compound semiconductor including at least nitrogen, gallium, and arsenic has a lattice constant identical or close to that of the GaAs semiconductor, and thus is free of excessive crystal strains, so that better oscillation characteristics and reliability can be realized in the optical semiconductor device without structural limitations even in the light-emitting devices that generate light of an oscillation wavelength of 1 micrometer or longer.

Examples of the III-V compound semiconductor including at least nitrogen, gallium, and arsenic are GaNAs and GaInNAs semiconductors. These semiconductors are new materials that have recently been developed. Their compositions of constituent elements (Ga, In, N, As) can be adjusted to obtain the following semiconductor material: semiconductor material lattice-matched to GaAs semiconductor; semiconductor material having a lattice constant close to that of GaAs semiconductor (with a lattice mismatch within ±2 percent); and semiconductor material for generating light having a wavelength of 0.9 micrometers or longer. Therefore, a long wavelength semiconductor light-emitting device can be realized on a GaAs semiconductor layer or GaAs substrate.

GaNAs semiconductors, GaInNAs semiconductors, and the like may further be doped with antimony (Sb) and/or phosphorus (P) as a V group member. Antimony element, acting as a so-called surfactant, can restrain the three-dimensional growth of GaInNAs semiconductors, thereby being effective in the improvement of the crystal quality of GaNAs and GaInNAs semiconductors. Phosphorus element is effective in the reduction of the local crystal strains within GaNAs and GaInNAs semiconductors, and in the increase of the number of nitrogen atoms taken into crystals as a V group element. GaInNAsP semiconductors are advantageous in that there is no difficulty in growing the crystals due to the miscibility gap in the phase diagram.

The semiconductor light-emitting devices in accordance with the first and second embodiments may include a cladding layer made of an Al_{X}Ga_{1-X}As semiconductor (0≦X≦1) and/or an (Al_{X}Ga_{1-X})_{Y}In_{1-Y}P semiconductor (0≦X≦1) that lattice-matches to GaAs semiconductor. Using these materials can improve the confinement of carriers. Among semiconductor materials in an InP/InGaAsP long-wavelength semiconductor laser device, InP semiconductor exhibits the largest band gap of 2.16×10⁻¹⁹ joules (1.35 eV). If a cladding layer of this semiconductor laser device is made of InP semiconductor, the band gap difference between the cladding layer and the active layer cannot be made large, and thus the carrier confinement cannot be improved.

The (Al_{X}Ga_{1-X})_{Y}In_{1-Y}P semiconductor (0≦X≦1) lattice-matched to GaAs semiconductor has a band gap value within the range of 3.06×10⁻¹⁹ joules (1.91 eV) or greater but not greater than 3.92×10⁻¹⁹ joules (2.45 eV) as the composition X of Al changes. The Al_{X}Ga_{1-X}As semiconductor (0≦X≦1) has a band gap value within the range of 2.27×10⁻¹⁹ joules (1.42 eV) or greater but not greater than 3.19×10⁻¹⁹ joules (1.99 eV) as the composition X of Al changes. Accordingly, the band gap difference between the cladding layer and the active layer is made greater than that in InP/GaInAsP semiconductor laser, and the confinement of carriers into the active layer can be improved. Therefore, the temperature characteristic of the semiconductor light-emitting device can be improved.

An active layer may be made of at least one of the following semiconductor material: GaInNAs; GaNAs; GaNAsSb; GaNAsP; GaNAsSbP; GaInNAsSb; GaInNAsP; and GaInNAsSbP semiconductors, and a cladding layer may be made of an (Al_{X}Ga_{1-X})_{Y}In_{1-Y}P semiconductor (0≦X≦1) or an Al_{X}Ga_{1-X}As semiconductor (0≦X≦1). Since a semiconductor optical device generating light of the oscillation wavelength of 1.3 micrometer band has an active layer of a band gap of about 1.53×10⁻¹⁹ joules (0.954 eV), the band gap difference between the active layer and the cladding layer realized by use of the AlGaInP cladding layer is 1.53×10⁻¹⁹ joules (0.956 eV) at the minimum and 2.4×10⁻¹⁹ joules (1.496 eV) at the maximum, and the band gap difference between the active layer and the cladding layer realized by use of the AlGaAs cladding layer is 0.75×10⁻¹⁹ joules (0.466 eV) at the minimum and 1.66×10⁻¹⁹ joules (1.036 eV) at the maximum.

Since a semiconductor optical device generating light of the oscillation wavelength of 1.55 micrometer band, on the other hand, has the active layer of a band gap of about 1.28×10⁻¹⁹ joules (0.8 eV), the band gap difference between the active layer and the cladding layer realized by use of the AlGaInP cladding layer is 1.78×10⁻¹⁹ joules (1.11 eV) at the minimum and 2.64×10⁻¹⁹ joules (1.65 eV) at the maximum, and the band gap difference between the active layer and the cladding layer realized by use of the AlGaAs cladding layer is 0.99×10⁻¹⁹ joules (0.62 eV) at the minimum and 1.91×10⁻¹⁹ joules (1.19 eV) at the maximum.

As the Aluminum composition increases in Al_{X}Ga_{1-X}As semiconductor (0≦X≦1) and (Al_{X}Ga_{1-X})_{Y}In_{1-Y}P semiconductor (0≦X≦1) that lattice-match to GaAs semiconductor, the band gap increases and the refractive index decreases. If the cladding layer and the current block layer are made of semiconductor material with a relatively smaller aluminum composition and semiconductor material with a relatively larger aluminum composition, respectively, the cladding layer has a refractive index higher than the refractive indices of the current block layers. Therefore, the effective refractive index of a stripe region located between the current block layers can be made higher than that of the current block layers. This structure realizes a refractive index guiding in the lateral transverse direction, thereby realizing a low threshold current in the semiconductor laser device. The refractive index guiding structure stabilizes the confinement of light in the lateral transverse direction, and thus enables the semiconductor laser device to achieve a single-mode oscillation in a fundamental lateral transverse mode. The semiconductor laser device exhibits a single-peak far field pattern (FFP), so that optical coupling between the optical fiber and the semiconductor laser device is enhanced. Therefore, semiconductor laser devices of the embodiments can improve semiconductor laser characteristics over anti refractive index guiding type InP buried ridge type laser devices.

If the current block semiconductor region is made of (Al_{X}Ga_{1-X})_{Y}In_{1-Y}P semiconductor (0≦X≦1) and/or Al_{X}Ga_{1-X}As semiconductor (0≦X≦1) which has a band gap greater than that of InP semiconductor, the heterobarrier between the active layer and the current block semiconductor region can be made greater, and thus the confinement of carriers into the active layer is further enhanced. As compared with InP/GaInAsP buried heterostructure semiconductor laser devices, the semiconductor laser device according to the present embodiments has the following advantages: the threshold current is lowered; the slope efficiency is increased; and the temperature characteristic is further improved.

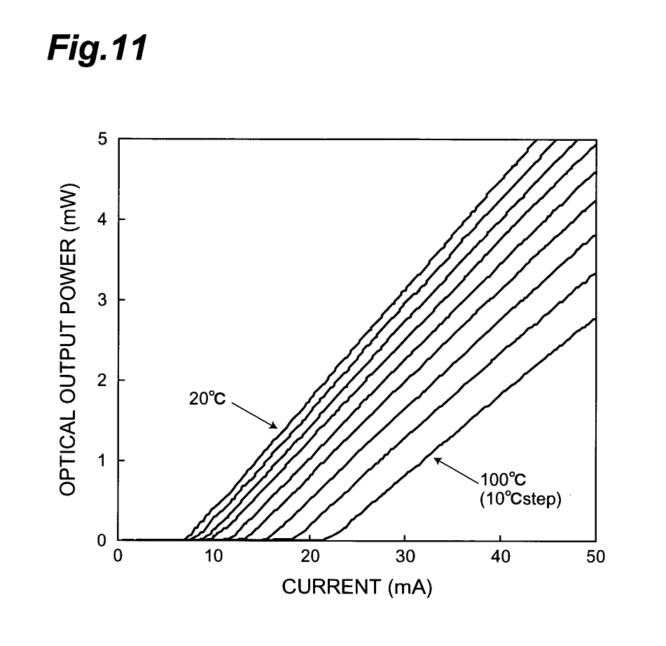

FIG. 11 is a graph showing the current versus optical output characteristics of a GaInNAs laser diode in several operation temperatures. This laser diode has a structure as shown in FIG. 10. The detail of the laser diode is as follows:

Substrate 61: GaAs substrate;

Active layer 55: GaInNAs (quantum well);

SCH layers 75 and 77: GaAs semiconductor;

Heterobarrier alleviating layer 81: GaInAsP;

Current block layers 59a and 59b: GaInP; and

Cavity length: 900 micrometers.

Both facets of the laser diode are uncoated. The laser diode generates light in 1.3 micrometers band. As can be seen from FIG. 11, the laser diode exhibits a small threshold current of about 20 milliamperes at 100 degrees Celsius and an excellent linearity in the optical output. The characteristic temperature of the laser diode is 80 Kelvin. It is difficult for the InP/GaInAsP semiconductor laser diodes to oscillate in such a high temperature range of 80 to 100 degrees Celsius. Therefore, it is clear that the temperature characteristics have been improved in the GaInNAs laser diode.

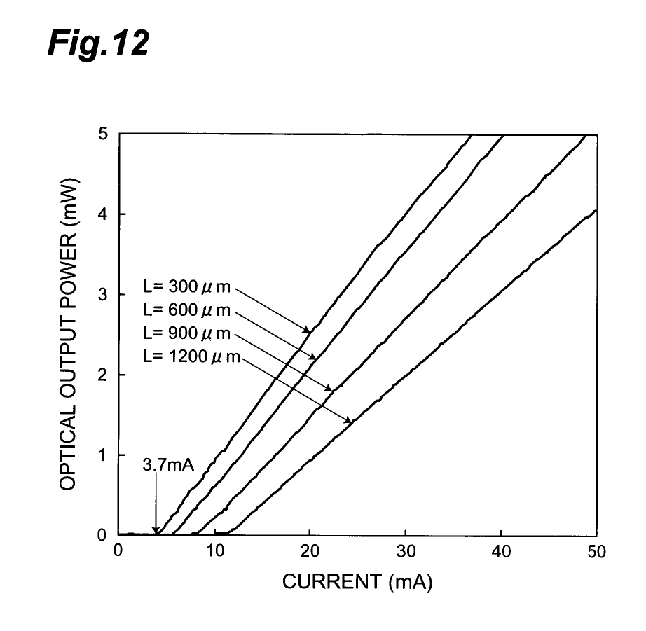

FIG. 12 is a graph showing the current versus optical output characteristics of the GaInNAs laser diode at a room temperature. A GaInNAs laser diode having a cavity length of 300 micrometers has a threshold current of 3.7 milliamperes. A GaInNAs laser diode having a cavity length of 1200 micrometers has a threshold current as small as 10 milliamperes or slight more. The threshold current and the temperature characteristics are improved by using the cladding layers and the current block layers of GaInP semiconductor, thereby enhancing the confinement of carries to the active layer.

In the semiconductor optical devices 1 and 51, the active layer may have a quantum well structure. For example, the quantum well structure may be one of SQW and MQW structures, but the structure of the active layer is not limited thereto. For example, a well layer can be made of the same material as that of the active layer, whereas a barrier layer can be made of the same material as that of the SCH layers, such as AlGaAs, GaAs, or GaInAsP semiconductor.

In the semiconductor light-emitting devices according to the first and second embodiments, the SCH layers are made of material having a refractive index between that of the active layer and that of the cladding layer. In order to achieve favorable confinement of carriers into the active layer, the SCH layers are made of material exhibiting a photoluminescence wavelength between that of the active layer and that of the cladding layer. In order to realize the above semiconductor light-emitting devices, the following combination can be used: the cladding layer made of (Al_{X}Ga_{1-X})_{Y}In_{1-Y}P semiconductor (0≦X≦1) or Al_{X}Ga_{1-X}As semiconductor (0≦X≦1); and the SCH layers made of GaInAsP semiconductor that lattice-matches to GaAs semiconductor and/or Al_{X}Ga_{1-X}As semiconductor (0≦X≦1). Using the SCH layers enhances the confinement of light into the active layer, thus improving the oscillation characteristics of the semiconductor light-emitting devices, such as a low threshold current and an excellent temperature characteristic. In particular, the SCH layers works effectively if the active layer has a quantum well constituted by very thin films.

The semiconductor light-emitting devices in accordance with the first and second embodiments may have a heterobarrier alleviating layer provided between the cladding layer and the SCH layer or active layer. A heterobarrier is produced at the heterostructure interface between the following layers: the cladding layer and active layer; and the SCH layer and cladding layer. The height of the heterobarrier depends on the band gap difference between the semiconductor materials thereof. This heterobarrier is known as a spike or notch, and has a wedge shape in an energy band diagram. This heterobarrier works as a barrier ΔEc for electrons in a conduction band and causes electric resistance thereto, and works as a barrier, ΔEv, for holes in a valence band and causes electric resistance thereto. The combination of an (Al_{X}Ga_{1-X})_{Y}In_{1-Y}P cladding layer and a GaAs SCH layer forms a p-n junction having a large heterobarrier in the valence band, for example. This heterobarrier increase the electric resistance within the semiconductor light-emitting device, thereby generating greater heat in the semiconductor light-emitting device. Further, this heterobarrier degrades the efficiency of carrier injection into the active layer. In particular, majority carriers in p-type semiconductors are holes, which exhibit low mobility due to their large effective mass. Therefore, they are trapped at the hetero-barrier, which results in a low efficiency of hole injection into the active layer. Hence, the large heterobarrier may be one of causes that degrade the long-term reliability and high output characteristic of the semiconductor light-emitting device, and so on. Lowering the heterobarrier is important to produce a semiconductor light-emitting device with the improved device characteristics and long-term reliability. The heterobarrier alleviating layer is useful for lowering the heterobarrier.

The following material can be used for the heterobarrier alleviating layer: (Al_{X}Ga_{1-X})_{Y}In_{1-Y}P semiconductor (0≦X≦1); Al_{X}Ga_{1-X}As semiconductor (0≦X≦1); and Ga_{X}In_{1-X}As_{Y}P_{1-Y} semiconductor, for example. These semiconductors can be used in the semiconductor light-emitting device having a cladding layer made of (Al_{X}Ga_{1-X})_{Y}In_{1-Y}P semiconductor (0≦X≦1) and/or Al_{X}Ga_{1-X}As semiconductor (0≦X≦1), and an SCH layer made of Al_{X}Ga_{1-X}As semiconductor (0≦X≦1) and/or Ga_{X}In_{1-X}As_{Y}P_{1-Y} semiconductor (about 0.5≦X≦1, 0≦Y≦1) lattice-matched to GaAs semiconductor.

The material of the heterobarrier alleviating layer may have a composition attaining a lattice mismatch in a range of −2 percent or more but not greater than +2 percent with respect to the lattice constant of a semiconductor substrate. In general, the heterobarrier alleviating layer has a thickness smaller than its critical film thickness. The film thickness of the heterobarrier alleviating layer is, for example, in a range of 5 nanometers or more but not greater than 10 nanometers, preferably 5 nanometers. If the lattice mismatch falls within this range, crystal defects are hard to occur. The acceptable range of lattice mismatch is widened, and thus the range of the composition of semiconductor material is expanded. If the cladding layer is made of Al_{X}Ga_{1-X}As semiconductor (0≦X≦1) or (Al_{X}Ga_{1-X})_{Y}In_{1-Y}P semiconductor (0≦X≦1) that lattice-matches to GaAs semiconductor and the SCH semiconductor layer is made of Al_{X}Ga_{1-X}As semiconductor (0≦X≦1) or Ga_{X}In_{1-X}As_{Y}P_{1-Y} semiconductor (about 0.5≦X≦1, 0≦Y≦1) that lattice-matches to GaAs semiconductor, (Al_{X}Ga_{1-X})_{Y}In_{1-Y}P semiconductor and/or Ga_{X}In_{1-X}As_{Y}P_{1-Y} semiconductor can be used to form a strained heterobarrier alleviating layer, for example.

In the semiconductor light-emitting device in accordance with the second embodiment, a semiconductor film of the first conductivity type is formed on a substrate. Semiconductor films constituting a light-emitting region are then formed on the semiconductor film of the first conductivity type, and thereafter a semiconductor film of the second conductivity type is formed on the semiconductor films constituting a light-emitting region. After these semiconductor films constituting a light-emitting region and the semiconductor film at the second conductivity type are formed, the semiconductor films are etched selectively against the semiconductor film of the first conductivity type. This selective etching is performed using a predetermined etchant. This etchant can etch the semiconductor films constituting the light-emitting region and the second conductivity type semiconductor film, but cannot etch the first conductivity type semiconductor region, thereby forming a semiconductor ridge.

In InP/GaInAsP long wavelength laser devices, Br methanol is typically used for etching to form a semiconductor ridge. Since Br methanol has no etching selectivity for InP semiconductor of the lower cladding layer (first conductivity type semiconductor region), the lower cladding layer is also etched in the etching step of forming the ridge. Due to volatility of Br methanol, its etching rate is changed with time. Slight fluctuations in temperature, concentration, and mixing ratio of the etching solution cause the etching rate to vary for each the etching step. Consequently, etchant having a predetermined etching rate cannot be prepared for each etching step. In addition, in stirring the etching solution in which a wafer is soaked, the etching rates are varied on the surface of the wafer due to the difference in its stirring speed between an outer part and a center on the surface of the wafer. That is, the etching rate is fluctuated depending on the number of uses of the etching solution, and the depths of the ridges are varied on the wafer surface. With Br methanol, the amount of the side etching varies nonlinearly with the depth of the ridge. The width of the active layer is fluctuated depending on the nonlinear change of the depth of the ridge, thereby generating nonlinear variations in the width of the active layer. The nonlinear variations in the width of the active layer deteriorate the reproducibility and uniformity of laser characteristics.

However, in the semiconductor optical device in accordance with the second embodiment, a predetermined etching solution (e.g., phosphoric acid etchant) may be used for selectively etching the semiconductor films of the SCH layer and the active layer against the lower cladding layer in the semiconductor optical device constituted by the following: the cladding layer made of (Al_{X}Ga_{1-X})_{Y}In_{1-Y}P semiconductor (0≦X≦1) lattice-matched to GaAs semiconductor; the SCH semiconductor layer made of Al_{X}Ga_{1-X}As semiconductor (0≦X≦1) or Ga_{X}In_{1-X}As_{Y}P_{1-Y} semiconductor (about 0.5≦X≦1, 0≦Y≦1) that lattice-matches to GaAs semiconductor; and the active layer made of III-V semiconductor material including nitrogen (e.g., GaInNAs, GaNAs, GaNAsSb, GaNAsP, GaNAsSbP, GaInNAsSb, GaInNAsP, and GaInNAsSbP semiconductors), for example. Thus, the semiconductor optical device having a buried heterostructure in the second embodiment is obtained. In the semiconductor light-emitting device in accordance with the second embodiment, the semiconductor layer provided below the active layer or SCH layer functions as an etch stop layer. Therefore, the ridge depth exhibits favorable reproducibility and uniformity on the wafer. Consequently, the reproducibility and the uniformity on the wafer are improved in the width of the active layer. The semiconductor light-emitting device may further include a heterobarrier alleviating layer made of (Al_{X}Ga_{1-X})_{Y}In_{1-Y}P semiconductor (0≦X≦1), Al_{X}Ga_{1-X}As semiconductor (0≦X≦1), and/or Ga_{X}In_{1-X}As_{Y}P_{1-Y} semiconductor, in order to reduce the internal resistance.

As explained in the foregoing, the semiconductor light-emitting devices in accordance with the first and second embodiments can solve some technical problems which have not been overcome by InGaAsP/InP semiconductor optical devices. For example, the semiconductor light-emitting devices in accordance with the first and second embodiments can solve problems in terms of high temperature characteristics which have occurred in InGaAsP/InP semiconductor laser devices. Hence, the semiconductor light-emitting devices in accordance with the first and second embodiments have advantageous temperature characteristics superior to InGaAsP/InP semiconductor optical devices.

Having described and illustrated the principle of the invention in a preferred embodiment thereof, it is appreciated by those having skill in the art that the invention can be modified in arrangement and detail without departing from such principles. For example, the semiconductor optical device encompasses not only semiconductor light-emitting devices, but also semiconductor laser devices, semiconductor optical amplifier devices, semiconductor optical integrated devices including EA modulators, and the like, as well as integrated devices integrating these devices. Details of structures of these devices can be modified as necessary. We therefore claim all modifications and variations coming within the spirit and scope of the following claims.

What is claimed is:

1. A semiconductor optical device comprising:
a first conductivity type semiconductor region, provided on a surface of GaAs semiconductor, having first and second semiconductor portions, said first semiconductor portion having a primary surface, said primary surface having a first area and a second area, said first area being provided between said second area, said second semiconductor portion having a pair of side surfaces, said second semiconductor portion being provided on the first area of said first semiconductor portion;
an active layer, provided on said second semiconductor portion of said first conductivity type semiconductor region, having a pair of side surfaces;
a second conductivity type semiconductor layer, provided on said active layer, having a pair of side surfaces; and
a current block semiconductor region for confining carriers to said second semiconductor portion, said active layer, and said second conductivity type semiconductor layer;
wherein the current block semiconductor region is provided on the second area of the first semiconductor portion of the first conductivity type semiconductor region, said surfaces of said second semiconductor portion, said side surfaces of said active layer, and said side surfaces of said second conductivity type semiconductor layer;
wherein said active layer is made of III-V compound semiconductor including at least nitrogen (N) as a V group member; and
wherein said active layer is provided so as to generate light having a wavelength of 0.9 micrometers or longer.

2. The semiconductor optical device according to claim 1, wherein said active layer is made of III-V compound semiconductor including gallium (Ga) as a III group member, and
wherein said III-V compound semiconductor of said active layer includes at least arsenic (As) as a V group member.

3. The semiconductor optical device according to claim 1, wherein said active layer is made of at least one of GaInNAs semiconductor; GaNAs semiconductor, GaNAsSb semiconductor, GaNAsP semiconductor, GaNAsSbP semiconductor, GaInNAsSb semiconductor, GaInNAsP semiconductor and GaInNAsSbP semiconductor.

4. The semiconductor optical device according to claim 1, wherein a refractive index of said second conductivity type semiconductor layer is higher than that of said current block semiconductor region.

5. The semiconductor optical device according to claim 1, further comprising an additional semiconductor layer containing III-V compound semiconductor;
wherein said additional semiconductor layer is provided between said first conductivity type semiconductor region and said active layer; and
wherein a photoluminescence wavelength of said III-V compound semiconductor is between that of said active layer and that of said first conductivity type semiconductor region.

6. The semiconductor optical device according to claim 1, further comprising an additional semiconductor layer containing III-V compound semiconductor;
wherein said additional semiconductor layer is provided between said second conductivity type semiconductor layer and said active layer; and
wherein a photoluminescence wavelength of said III-V compound semiconductor is between that of said active layer and that of said second conductivity type semiconductor layer.

7. The semiconductor optical device according to claim 1, further comprising a first SCH layer provided between said first conductivity type semiconductor region and said active layer; and
a second SCH layer provided between said active layer and said second conductivity type semiconductor layer.

8. The semiconductor optical device according to claim 7, further comprising an additional semiconductor layer containing III-V compound semiconductor;
wherein said additional semiconductor layer is provided between said first conductivity type semiconductor region and said first SCH layer; and
wherein a photoluminescence wavelength of said III-V compound semiconductor is between that of said first SCH layer and that of said first conductivity type semiconductor layer.

9. The semiconductor optical device according to claim 7, further comprising an additional semiconductor layer containing III-V compound semiconductor;
wherein said additional semiconductor layer is provided between said second conductivity type semiconductor layer and said second SCH layer;
wherein a photoluminescence wavelength of said III-V compound semiconductor is between that of said second SCH layer and that of said second conductivity type semiconductor layer.

10. The semiconductor optical device according to claim 1, wherein said current block semiconductor region comprises first and second current block layers;
wherein said first conductivity type semiconductor region is made of (Al_{X1}Ga_{1-X1})_{Y1}In_{1-Y1}P semiconductor, where a composition X1 has a value within the range of zero or greater but not greater than 1;
wherein said second conductivity type semiconductor layer is made of (Al_{X2}Ga_{1-X2})_{Y2}In_{1-Y2}P semiconductor, where a composition X2 has a value within the range of zero or greater but not greater than 1; and
wherein said first and second current block layers are made of (Al_{X3}Ga_{1-X3})_{Y3}In_{1-Y3}P semiconductor, where a composition X3 has a value within the range of zero or greater but not greater than 1.

11. The semiconductor optical device according to claim 1, wherein said current block semiconductor region comprises first and second current block layers;
wherein said first conductivity type semiconductor region is made of an Al_{X1}Ga_{1-X1}As semiconductor, where a composition X1 has a value within the range of zero or greater but not greater than 1;
wherein said second conductivity type semiconductor layer is made of an Al_{X2}Ga_{1-X2}As semiconductor, where a composition X2 has a value within the range of zero or greater but not greater than 1; and
wherein said first and second current block layers are made of Al_{X3}Ga_{1-X3}As semiconductor, where a composition X3 has a value within the range of zero or greater but not greater than 1.

12. The semiconductor optical device according to claim 7,
wherein said first and second SCH layers are made of one of Al_{X}Ga_{1-X}As semiconductor (0≦X≦1) and Ga_{X}In_{1-X}As_{Y}P_{1-Y} semiconductor (about 0.5≦X≦1, 0≦Y≦1), said Ga_{X}In_{1-X}As_{Y}P_{1-Y} semiconductor lattice-matched to GaAs semiconductor.

13. The semiconductor optical device according to claim 1, wherein said current block semiconductor region comprises first and second current block layers; and
wherein said first and second current block semiconductor layers are made of material not containing aluminum as a III group element.

14. The semiconductor optical device according to claim 1, wherein said current block semiconductor region comprises first and second current block layers; and
wherein said first and second current block semiconductor layers are made of material not containing aluminum as a III group element,
wherein said first conductivity type semiconductor region is made of material not containing aluminum as a III group element, and
wherein said second conductivity type semiconductor layer is made of material not containing aluminum as a III group element.

15. The semiconductor optical device according to claim 1, wherein said surface of GaAs semiconductor is provided by one of a GaAs semiconductor layer and a gallium arsenide substrate.

16. The semiconductor optical device according to claim 1, wherein said semiconductor optical device is constituted to provide at least one of a semiconductor laser diode, a semiconductor optical amplifier, and an electro-absorption modulator.

17. A semiconductor optical device comprising:
a first conductivity type semiconductor region, provided on a surface of GaAs semiconductor, including a primary surface having a first area and a second area, said first area being provided between said second areas;
a semiconductor ridge including an active layer provided on said first area of said first conductivity type semiconductor region and a second conductivity type semiconductor layer provided on said active layer, said semiconductor ridge having a pair of side surfaces; and
a current block semiconductor region provided on said second area of said first conductivity type semiconductor region and said side surfaces of said semiconductor ridge, said current block semiconductor region being provided for confining carriers to said semiconductor ridge;
wherein said active layer is made of III-V compound semiconductor including at least nitrogen (N) as a V group member; and
wherein said active layer is provided to generate light having a wavelength of 0.9 micrometers or longer.

18. The semiconductor optical device according to claim 17, wherein said first conductivity type semiconductor region is made of semiconductor material enabling said first conductivity type semiconductor region to be a etch stopper resistant to etchant for etching said active layer and said second conductivity type semiconductor layer.

19. The semiconductor optical device according to claim 17, wherein said active layer is made of III-V compound semiconductor including gallium (Ga) as a III group member, and
wherein said III-V compound semiconductor of said active layer includes at least arsenic (As) as a V group member.

20. The semiconductor optical device according to claim 17, wherein said active layer is made of at least one of GaInNAs semiconductor, GaNAs semiconductor, GaNAsSb semiconductor, GaNAsP semiconductor, GaNAsSbP semiconductor, GaInNAsSb semiconductor, GaInNAsP semiconductor and GaInNAsSbP semiconductor.

21. The semiconductor optical device according to claim 17, wherein said second conductivity type semiconductor layer has a refractive index higher than that of said current block semiconductor region.

22. The semiconductor optical device according to claim 17, further comprising an additional semiconductor layer containing III-V compound semiconductor;
wherein said additional semiconductor layer is provided between said first conductivity type semiconductor region and said active layer; and
wherein a photoluminescence wavelength of said III-V compound semiconductor is between that of said active layer and that of said first conductivity type semiconductor region.

23. The semiconductor optical device according to claim 17, further comprising an additional semiconductor layer containing III-V compound semiconductor;
wherein said additional semiconductor layer is provided between said second conductivity type semiconductor layer and said active layer; and
wherein a photoluminescence wavelength of said III-V compound semiconductor is between that of said active layer and that of said second conductivity type semiconductor layer.

24. The semiconductor optical device according to claim 17, further comprising a first SCH layer provided between said first conductivity type semiconductor region and said active layer; and
a second SCH layer provided between said active layer and said second conductivity type semiconductor layer.

25. The semiconductor optical device according to claim 24, further comprising an additional semiconductor layer containing III-V compound semiconductor;
wherein said additional semiconductor layer is provided between said first conductivity type semiconductor region and said first SCH layer; and
wherein a photoluminescence wavelength of said III-V compound semiconductor is between that of said first SCH layer and that of said first conductivity type semiconductor layer.

26. The semiconductor optical device according to claim 24, further comprising an additional semiconductor layer containing III-V compound semiconductor;
wherein said additional semiconductor layer is provided between said second conductivity type semiconductor layer and said second SCH layer;
wherein a photoluminescence wavelength of said III-V compound semiconductor is between that of said second SCH layer and that of said second conductivity type semiconductor layer.

27. The semiconductor optical device according to claim 17, wherein said current block semiconductor region comprises first and second current block layers;
wherein said first conductivity type semiconductor region is made of (Al_{X1}Ga_{1-X1})_{Y1}In_{1-Y1}P semiconductor, where a composition X1 has a value within the range of zero or greater but not greater than 1;
wherein said second conductivity type semiconductor layer is made of (Al_{X2}Ga_{1-X2})_{Y2}In_{1-Y2}P semiconductor, where a composition X2 has a value within the range of zero or greater but not greater than 1; and
wherein said first and second current block layers are made of (Al_{X3}Ga_{1-X3})_{Y3}In_{1-Y3}P semiconductor, where a composition X3 has a value within the range of zero or greater but not greater than 1.

28. The semiconductor optical device according to claim 17, wherein said current block semiconductor region comprises first and second current block layers;
wherein said first conductivity type semiconductor region is made of an Al_{X1}Ga_{1-X1}As semiconductor, where a composition X1 has a value within the range of zero or greater but not greater than 1;
wherein said second conductivity type semiconductor layer is made of an Al_{X2}Ga_{1-X2}As semiconductor, where a composition X2 has a value within the range of zero or greater but not greater than 1; and
wherein said first and second current block layers are made of Al_{X3}Ga_{1-X3}As semiconductor, where a composition X3 has a value within the range of zero or greater but not greater than 1.

29. The semiconductor optical device according to claim 24,
wherein said first and second SCH layers is made of one of Al_{X}Ga_{1-X}As semiconductor (0≦X≦1) and Ga_{X}In_{1-X}As_{Y}P_{1-Y} semiconductor (about 0.5≦X≦1, 0≦Y≦1), said Ga_{X}In_{1-X}As_{Y}P_{1-Y} semiconductor lattice-matched to GaAs semiconductor.

30. The semiconductor optical device according to claim 17, wherein said current block semiconductor region comprises first and second current block layers; and
wherein said first and second current block semiconductor layers are made of material not containing aluminum as a III group element.

31. The semiconductor optical device according to claim 17, wherein said current block semiconductor region comprises first and second current block layers; and
wherein said first and second current block semiconductor layers are made of material not containing aluminum as a III group element
wherein said first conductivity type semiconductor region is made of material not containing aluminum as a III group element
wherein said second conductivity type semiconductor layer is made of material not containing aluminum as a III group element.

32. The semiconductor optical device according to claim 17, wherein said surface of GaAs semiconductor is provided by one of a GaAs semiconductor layer and a gallium arsenide substrate.

33. The semiconductor optical device according to claim 17, wherein said semiconductor optical device is constituted to provide at least one of a semiconductor laser diode, a semiconductor optical amplifier, and an electro-absorption modulator.
